(19) United States
(12) Patent Application Publication
(10) Pub. No.: US 2013/0256007 A1
(43) Pub. Date: Oct. 3, 2013

(54) WIRING BOARD WITH BUILT-IN ELECTRONIC COMPONENT AND METHOD FOR MANUFACTURING THE SAME

(71) Applicant: IBIDEN CO., LTD., Ogaki-shi (JP)

(72) Inventors: Toshiki Furutani, Ogaki-shi (JP); Yukinobu Mikado, Ogaki-shi (JP); Mitsuhiro Tomikawa, Ogaki-shi (JP); Yuki Tanaka, Ogaki-shi (JP)

(73) Assignee: IBIDEN CO., LTD., Ogaki-shi (JP)

(21) Appl. No.: 13/729,998

(22) Filed: Dec. 28, 2012

Related U.S. Application Data
(60) Provisional application No. 61/616,653, filed on Mar. 28, 2012.

(51) Int. Cl. H05K 1/18; H05K 3/30

(52) U.S. Cl. CPC H05K 1/185; H05K 3/306
USPC 174/255; 29/837

(57) ABSTRACT

A wiring board includes a substrate having a cavity, an electronic component positioned in the cavity and having a first-side electrode on one side of the electronic component and a second-side electrode on the opposite side of the electronic component, an insulation layer formed on a surface of the substrate and the electronic component such that the insulation layer covers the electronic component positioned in the substrate, and a conductive layer formed on the surface of the substrate and including linear conductive patterns surrounding an opening of the cavity on the surface of the substrate. The linear conductive patterns include a first linear conductive pattern positioned adjacent to the first-side electrode and a second linear conductive pattern positioned adjacent to the second-side electrode such that the first linear conductive pattern and the second linear conductive pattern are insulated from each other.

### CROSS-REFERENCE TO RELATED APPLICATIONS

The present application is based upon and claims the benefit of priority from U.S. Application No. 61/616,653, filed Mar. 28, 2012, the entire contents of which are incorporated herein by reference.

### BACKGROUND OF THE INVENTION

1. Field of the Invention

The present invention relates to a wiring board with a built-in electronic component and to its manufacturing method.

2. Description of Background Art

Japanese Laid-Open Patent Publication No. 2001-345560 describes a wiring board with a built-in capacitor. In a wiring board described in Japanese Laid-Open Patent Publication No. 2001-345560, an electronic component (capacitor) is accommodated in a cavity (accommodation section) formed in the substrate, and a conductive layer on the substrate is positioned at a peripheral portion of the cavity (see FIG. 1(b) or the like in Japanese Laid-Open Patent Publication No. 2001-345560). The contents of Japanese Laid-Open Patent Publication No. 2001-345560 are incorporated herein in this application.

### SUMMARY OF THE INVENTION

According to one aspect of the present invention, a wiring board includes a substrate having a cavity, an electronic component positioned in the cavity and having a first-side electrode on one side of the electronic component and a second-side electrode on the opposite side of the electronic component, an insulation layer formed on a surface of the substrate and the electronic component such that the insulation layer covers the electronic component positioned in the substrate, and a conductive layer formed on the surface of the substrate and including linear conductive patterns surrounding an opening of the cavity on the surface of the substrate. The linear conductive patterns include a first linear conductive pattern positioned adjacent to the first-side electrode and a second linear conductive pattern positioned adjacent to the second-side electrode such that the first linear conductive pattern and the second linear conductive pattern are insulated from each other.

According to another aspect of the present invention, a method for manufacturing a wiring board with a built-in electronic component includes forming on a first surface of a substrate a conductive layer including linear conductive patterns surrounding a predetermined region of the first surface, forming in the predetermined region of the substrate a cavity having an opening at least on the first surface, positioning in the cavity an electronic component having a first-side electrode and a second-side electrode on an opposite side of the first-side electrode, and forming an insulation layer on the first surface of the substrate and the electronic component such that the insulation layer covers the electronic component. The forming of the cavity includes irradiating laser on the linear conductive patterns such that the region surrounded by the linear conductive patterns is cut out and that the cavity is formed in the predetermined region of the substrate, and the positioning of the electronic component includes placing the electronic component in the cavity such that the linear conductive patterns includes a first linear conductive pattern positioned adjacent to the first-side electrode and a second linear conductive pattern positioned adjacent to the second-side electrode and that the first linear conductive pattern and the second linear conductive pattern are insulated from each other at least through the forming of the insulation layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a wiring board according to an embodiment of the present invention;

FIG. 2 is a partially enlarged view of FIG. 1;

FIG. 3A is a view showing a first cross-sectional shape of a chip capacitor to be built into a wiring board according to the embodiment of the present invention;

FIG. 3B is a view showing a second cross-sectional shape of a chip capacitor to be built into a wiring board according to the embodiment of the present invention;

FIG. 4A is a plan view of a chip capacitor to be built into a wiring board according to the embodiment of the present invention;

FIG. 4B is a view showing electrodes formed on side surfaces of a chip capacitor to be built into a wiring board according to the embodiment of the present invention;

FIG. 5A is a plan view showing a state where an electronic component is accommodated in a cavity in a wiring board according to the embodiment of the present invention;

FIG. 5B is a partially enlarged view of FIG. 5A;

FIG. 6A, regarding the peripheral portions of a cavity formed in a wiring board according to the embodiment of the present invention, is a view showing a portion with which a second side electrode never makes contact, and a portion with which the second side electrode may make contact;

FIG. 6B, regarding the peripheral portions of a cavity formed in a wiring board according to the embodiment of the present invention, is a view showing a portion with which a first side electrode never makes contact, and a portion with which the first side electrode may make contact;

FIG. 7, regarding the peripheral portions of a cavity formed in a wiring board according to the embodiment of the present invention, is a view showing a portion with which a first side electrode may make contact but a second side electrode never makes contact, a portion with which the second side electrode may make contact but the first side electrode never makes contact, and a portion with which neither the first side electrode nor the second side electrode makes contact.

FIG. 8 is a view showing a wiring board where a ring-shaped conductive pattern without a break is formed on the peripheral portions of a cavity;

FIG. 9 is a view illustrating the difference between a wiring board according to the embodiment of the present invention and the wiring board shown in FIG. 8;

FIG. 10A is a cross-sectional view of a first conductive pattern surrounding a first-surface side opening of a cavity in a wiring board according to the embodiment of the present invention;

FIG. 10B is a cross-sectional view of a second conductive pattern surrounding a first-surface side opening of a cavity in a wiring board according to the embodiment of the present invention;

FIG. 11 is a view illustrating a step for forming a cavity in the substrate in a method for manufacturing a wiring board where a conductive layer of the substrate does not have a conductive pattern in a position corresponding to a peripheral portion of the cavity;

FIG. 12 is a flowchart showing a method for manufacturing a wiring board according to the embodiment of the present invention;

FIG. 13A, in the manufacturing method shown in FIG. 12, is a view illustrating a first step for forming conductive layers on a substrate;

FIG. 13B, in the manufacturing method shown in FIG. 12, is a view illustrating a second step for forming conductive layers on the substrate;

FIG. 13C, in the manufacturing method shown in FIG. 12, is a view illustrating a third step for forming conductive layers on the substrate;

FIG. 13D, in the manufacturing method shown in FIG. 12, is a view illustrating a fourth step for forming conductive layers on the substrate;

FIG. 14, in the manufacturing method shown in FIG. 12, is a view illustrating a step for forming a cavity in the substrate;

FIG. 15 is a partially enlarged view of FIG. 14;

FIG. 16A is a plan view showing an opening section (cavity) formed in the substrate in the step shown in FIG. 14;

FIG. 16B is a cross-sectional view of FIG. 16A;

FIG. 17, in the manufacturing method shown in FIG. 12, is a view illustrating a step for attaching the substrate with a cavity to a carrier;

FIG. 18, in the manufacturing method shown in FIG. 12, is a view illustrating a step for accommodating an electronic component in the cavity;

FIG. 19, in the manufacturing method shown in FIG. 12, is a view showing a state in which an electronic component is accommodated in the cavity;

FIG. 20, in the manufacturing method shown in FIG. 12, is a view illustrating a first step for filling insulator in a gap between a substrate and an electronic component in the cavity;

FIG. 21 is a view illustrating a second step subsequent to the step in FIG. 20;

FIG. 22 is a view illustrating a third step subsequent to the step in FIG. 21;

FIG. 23, in the manufacturing method shown in FIG. 12, is a view illustrating a step for removing the carrier from the substrate;

FIG. 24, in the manufacturing method shown in FIG. 12, is a view illustrating a first step for forming a lower buildup section;

FIG. 25 is a view illustrating a second step subsequent to the step in FIG. 24;

FIG. 26 is a view illustrating a third step subsequent to the step in FIG. 25;

FIG. 27 is a view illustrating a fourth step subsequent to the step in FIG. 26;

FIG. 28, in the manufacturing method shown in FIG. 12, is a view illustrating steps for forming upper buildup sections;

FIG. 29, in another embodiment of the present invention, is a view showing an example of a structure to make the electrical potential of conductive patterns surrounding an opening of a cavity the same as that of the electrodes of an electronic component;

FIG. 30, in yet another embodiment of the present invention, is a view showing an example where linear conductive patterns are formed on a substrate in addition to linear conductive patterns surrounding an opening of a cavity;

FIG. 31A, in yet another embodiment of the present invention, is a view showing a first planar shape of the linear conductive patterns surrounding an opening of the cavity;

FIG. 31B, in yet another embodiment of the present invention, is a view showing a second planar shape of the linear conductive patterns surrounding an opening of the cavity;

FIG. 31C, in yet another embodiment of the present invention, is a view showing a third planar shape of the linear conductive patterns surrounding an opening of the cavity;

FIG. 32, in yet another embodiment of the present invention, is a view showing an example where the entire first conductive pattern is formed in a peripheral portion with which a first side electrode of an electronic component may make contact but the second side electrode never makes contact, while the entire second conductive pattern is formed in a portion with which the second side electrode of the electronic component may make contact but the first side electrode never makes contact;

FIG. 33, in yet another embodiment of the present invention, is a view showing an example where a first conductive pattern and a second conductive pattern have asymmetrical shapes relative to the cavity;

FIG. 34A, in yet another embodiment of the present invention, is a view showing a first shape of a side surface of a linear conductive pattern surrounding an opening of the cavity;

FIG. 34B, in yet another embodiment of the present invention, is a view showing a second shape of a side surface of a linear conductive pattern surrounding an opening of the cavity;

FIG. 34C, in yet another embodiment of the present invention, is a view showing a third shape of a side surface of a linear conductive pattern surrounding an opening of a cavity;

FIG. 35A, in yet another embodiment of the present invention, is a view showing a first layer structure of a linear conductive pattern surrounding an opening of a cavity;

FIG. 35B, in yet another embodiment of the present invention, is a view showing a second layer structure of a linear conductive pattern surrounding an opening of a cavity;

FIG. 36, in yet another embodiment of the present invention, is a view showing an example where linear conductive patterns surrounding an opening of a cavity are formed on only one surface of a substrate;

FIG. 37, in yet another embodiment of the present invention, is a view showing a wiring board with multiple built-in electronic components;

FIG. 38, in yet another embodiment of the present invention, is a view showing an example where insulation layers of lower buildup sections contain core material and insulation layers of upper buildup sections do not contain core material;

FIG. 39, in yet another embodiment of the present invention, is a view showing a wiring board with a double-sided via structure;

FIG. 40, in yet another embodiment of the present invention, is a view showing a wiring board with a built-in electronic component where the electronic component is positioned in a non-penetrating opening section;

FIG. 41, in yet another embodiment of the present invention, is a view showing a wiring board having a substrate with a built-in metal plate;

FIG. 42A is a view illustrating a first step for manufacturing a substrate to be used in the wiring board shown in FIG. 41;

FIG. 42B is a view illustrating a second step subsequent to the step in FIG. 42A;

FIG. 43A, in yet another embodiment of the present invention, is a view illustrating a first step of a manufacturing method for insulating a first conductive pattern and a second conductive pattern after forming a cavity;

FIG. 43B is a view illustrating a second step subsequent to the step in FIG. 43A; and

FIG. 44, in yet another embodiment of the present invention, is a view illustrating a manufacturing method for removing a conductive layer on a substrate along the laser irradiation path while forming a cavity.

### DETAILED DESCRIPTION OF THE EMBODIMENTS

The embodiments will now be described with reference to the accompanying drawings, wherein like reference numerals designate corresponding or identical elements throughout the various drawings.

In the drawings, arrows (Z1, Z2) each indicate a lamination direction of a wiring board (or a thickness direction of the wiring board) corresponding to a normal line to the main surfaces (upper and lower surfaces) of the wiring board. On the other hand, arrows (X1, X2) and (Y1, Y2) each indicate a direction perpendicular to a lamination direction (or a direction to a side of each layer). Main surfaces of a wiring board are on the X-Y plane, and side surfaces of a wiring board are on the X-Z plane or the Y-Z plane. In a lamination direction, a side closer to the core is referred to as a lower layer (or inner-layer side), and a side farther from the core is referred to as an upper layer (or outer-layer side).

A conductive layer is a layer formed with one or multiple conductive patterns. A conductive layer may include a conductive pattern that forms an electrical circuit, such as wiring (including ground), a pad, a land or the like; or it may include a planar conductive pattern that does not form an electrical circuit.

Opening portions include notches, slits and so forth in addition to holes and grooves. Holes are not limited to penetrating holes, but non-penetrating holes are also included. Holes include via holes and through holes. In the following, a conductor formed in a via hole (wall surface or bottom surface) is referred to as a via conductor, and a conductor formed in a through hole (wall surface) is referred to as a through-hole conductor.

Plating includes wet plating such as electrolytic plating as well as dry plating such as PVD (physical vapor deposition) and CVD (chemical vapor deposition).

A side electrode of an electronic component is such an electrode that is formed on at least part of a side surface of the electronic component.

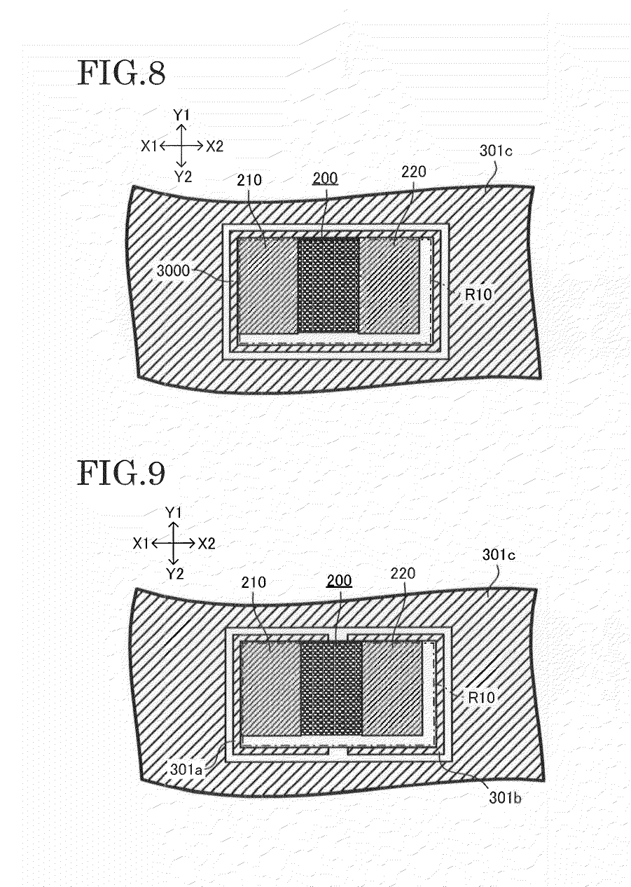

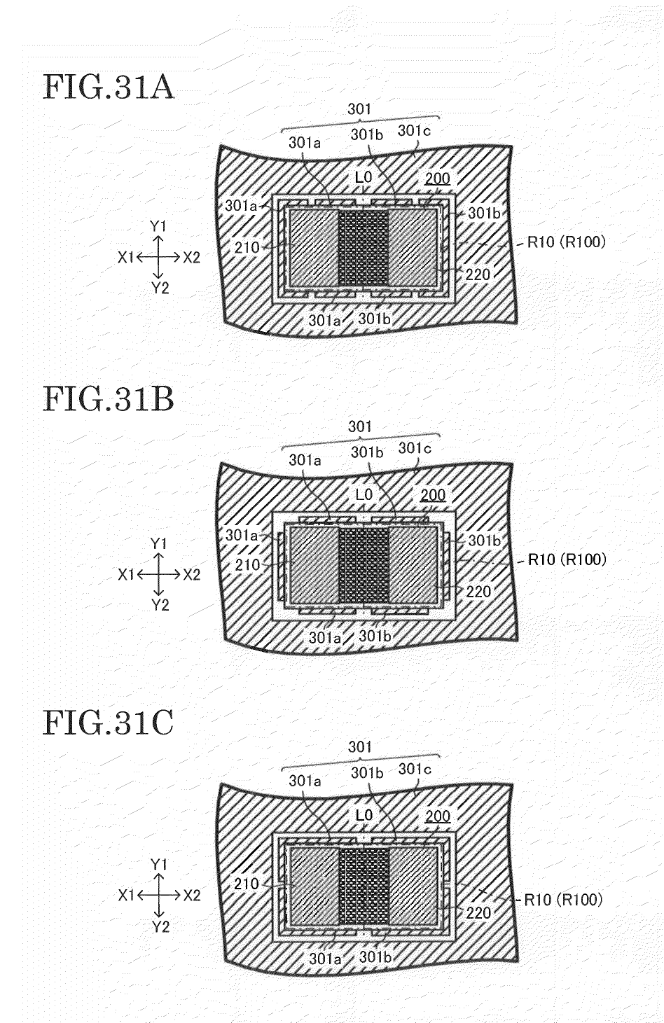

Surrounding includes situations where a region is completely closed by an unbroken ring (see FIG. 8), situations where a region is surrounded by a broken ring (multiple linear patterns) (see FIGS. 9, 31A˜31C), and so forth.

For an electronic component to be positioned in a cavity includes situations where the entire electronic component is completely accommodated in a cavity, and situations where only part of an electronic component is positioned in a cavity.

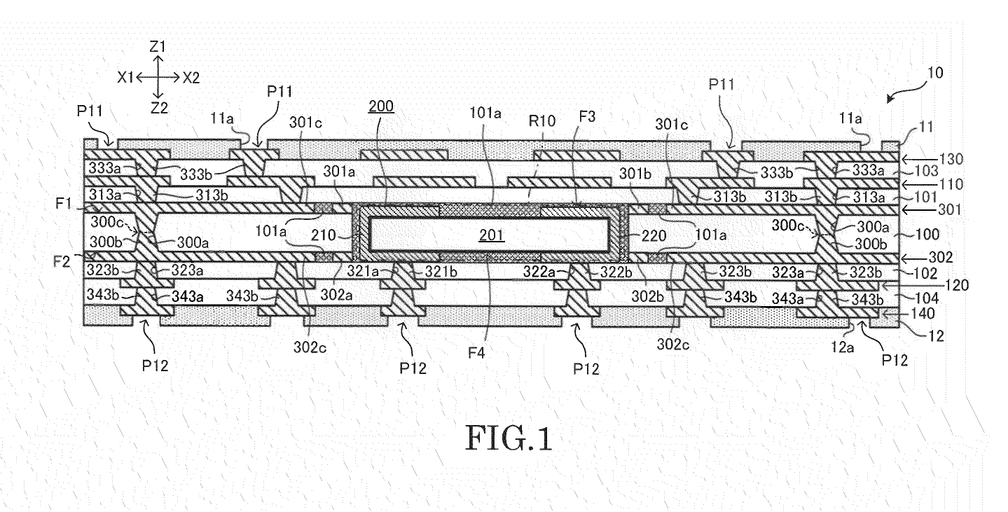

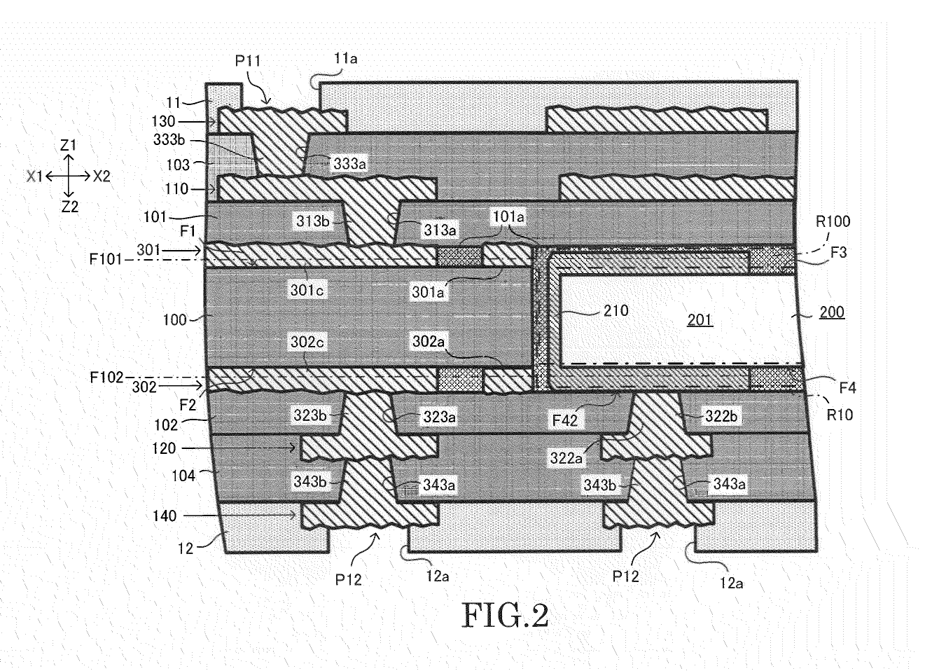

As shown in FIGS. 1 and 2 (partially enlarged view of FIG. 1), wiring board 10 (wiring board with a built-in electronic component) according to the present embodiment has the following: substrate 100 (insulative substrate), through-hole conductor (300b), insulation layers (101, 102, 103, 104) (each an interlayer insulation layer), conductive layers (301, 302, 110, 120, 130, 140), electronic component 200, via conductors (313b, 321b, 322b, 323b, 333b, 343b) and solder resists (11, 12). Wiring board 10 of the present embodiment is a rectangular rigid wiring board, for example. However, that is not the only option, and wiring board 10 may have any other shape than rectangular, and it may be a flexible wiring board.

In the present embodiment, substrate 100 is the core substrate of wiring board 10. Opening section (R100) is formed in substrate 100 (FIG. 2). Electronic component 200 is built into the core section of wiring board 10 by being positioned in opening section (R100). In wiring board 10 of the present embodiment, substrate 100, through-hole conductor (300b), conductive layers (301, 302) and electronic component 200 make up the core section. In the following, one of the upper and lower surfaces (two main surfaces) of substrate 100 is referred to as first surface (F1) and the other as second surface (F2). Also, of the upper and lower surfaces (two main surfaces) of electronic component 200, the surface facing the same direction as first surface (F1) is referred to as third surface (F3), and the other as fourth surface (F4).

Conductive layers, interlayer insulation layers and via conductors laminated on the core substrate correspond to buildup sections. In the following, a buildup section in a lowermost position is referred to as a lower buildup section, and a buildup section positioned farther up than the lower buildup section is referred to as an upper buildup section. In the present embodiment, the lower buildup sections are formed with insulation layers (101, 102), conductive layers (110, 120) and via conductors (313b, 321b, 322b, 323b). Also, the upper buildup sections are formed with insulation layers (103, 104), conductive layers (130, 140) and via conductors (333b, 343b).

Through hole (300a) is formed in substrate 100 (core substrate), and through-hole conductor (300b) is formed by filling conductor (such as copper plating) in through hole (300a). Through-hole conductor (300b) is shaped like an hourglass, for example. Namely, through-hole conductor (300b) has narrowed portion (300c), the width of through-hole conductor (300b) gradually decreases as it comes closer to narrowed portion (300c) from first surface (F1), and also gradually decreases as it comes closer to narrowed portion (300c) from second surface (F2). However, that is not the only option, and through-hole conductor (300b) may have any other shape; for example, it may have a substantially columnar shape.

Conductive layer 301 is formed on first surface (F1) of substrate 100, and conductive layer 302 is formed on second surface (F2) of substrate 100. Conductive layer 301 and conductive layer 302 are electrically connected to each other by through-hole conductor (300b). Conductive layers (301, 302) are each electrically connected to power source or ground, for example.

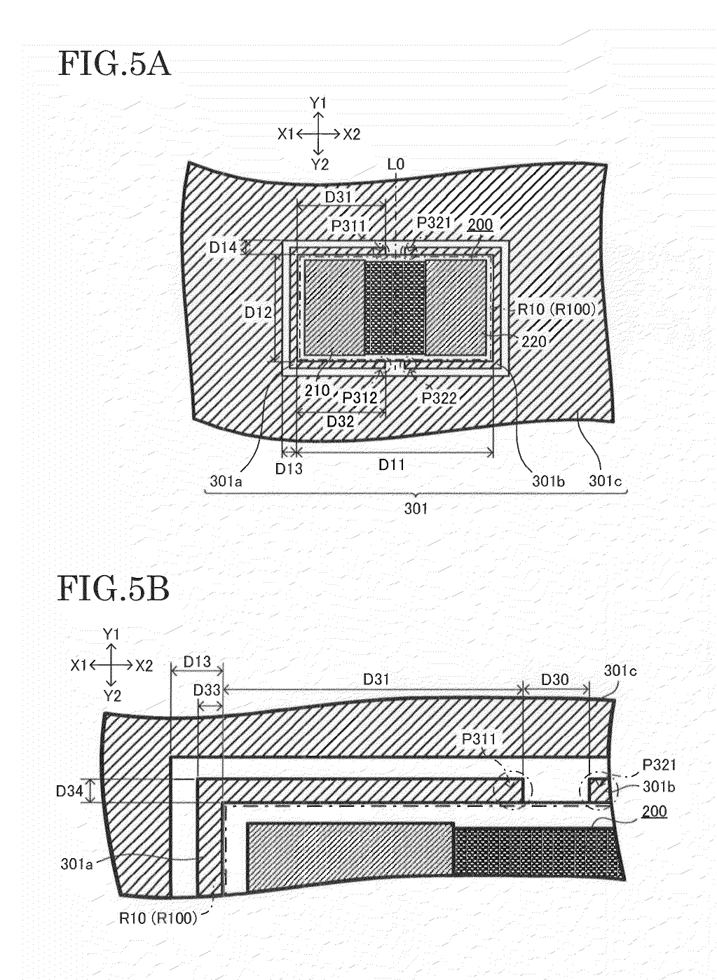

Conductive layer 301 includes linear conductive pattern (301a) (first conductive pattern), linear conductive pattern (301b) (second conductive pattern) and planar conductive pattern (301c). Conductive pattern 302 includes linear conductive pattern (302a) (first conductive pattern), linear conductive pattern (302b) (second conductive pattern) and planar conductive pattern (302c). Detailed description of the shapes of conductive patterns (301a, 301b, 301c) and the like are provided later (see FIGS. 5A and others).

Substrate 100 has opening section (R100) (a hole, for example) which penetrates from first surface (F1) to second surface (F2) of substrate 100. By forming opening section (R100) in substrate 100, cavity (R10) (accommodation section) is formed in the core section of wiring board 10, having a thickness from the upper surface of conductive layer 301 formed on one side of substrate 100 to the upper surface of conductive layer 302 formed on the other side. In the present embodiment, cavity (R10) is formed as a hole that penetrates through substrate 100. Cavity (R10) opens on first surface (F1) and on its opposing second surface (F2) respectively. Cavity (R10) is formed by a laser. The planar shape of cavity (R10) (including its measurements) is the same as that of opening section (R100).

Insulation layer 101 is formed on first surface (F1) of substrate 100 and on conductive layer 301. Insulation layer 102 is formed on second surface (F2) of substrate 100 and on conductive layer 302. Insulation layer 101 covers the opening on one side (first-surface (F1) side) of cavity (R10), and insulation layer 102 covers the opening on the other side (second-surface (F2) side) of cavity (R10).

In the present embodiment, the entire electronic component 200 is accommodated in cavity (R10). Electronic component 200 is positioned in a direction to a side of substrate 100 (in direction X or direction Y) by being placed in cavity (R10). It is not always required for electronic component 200 to be accommodated entirely in cavity (R10). It is an option for only part of electronic component 200 to be positioned in cavity (R10).

Conductive layer 110 is formed on insulation layer 101, and conductive layer 120 is formed on insulation layer 102.

Insulator (101a) is filled between electronic component 200 in cavity (R10) and substrate 100 and insulation layers (101, 102). In the present embodiment, insulator (101a) is made of insulative material (such as resin) that forms insulation layer 101 and the like (such as resin insulation layers). In the present embodiment, insulator (101a) has a greater thermal expansion coefficient than any of substrate 100 and electronic component 200.

Insulation layer 103 is formed on insulation layer 101 and on conductive layer 110, and insulation layer 104 is formed on insulation layer 102 and on conductive layer 120. Conductive layer 130 is formed on insulation layer 103, and conductive layer 140 is formed on insulation layer 104. In the present embodiment, conductive layers (130, 140) are outermost layers. However, that is not the only option, and more interlayer insulation layers and conductive layers may further be laminated.

Hole (313a) (via hole) is formed in insulation layer 101, and holes (321a, 322a, 323a) (via holes) are formed in insulation layer 102. Hole (333a) (via hole) is formed in insulation layer 103, and hole (343a) (via hole) is formed in insulation layer 104. By filling conductor (such as copper plating) in holes (313a, 321a, 322a, 323a, 333a, 343a), conductors in their respective holes become via conductors (313b, 321b, 322b, 323b, 333b, 343b) (each a filled conductor).

Via conductor (321b) is connected to electrode 210 of electronic component 200, and via conductor (322b) is connected to electrode 220 of electronic component 200. Via conductors (321b, 322b) are each formed in insulation layer 102. In the present embodiment, only one surface of electronic component 200 is connected to via conductors. In the following, such a structure is referred to as a single-sided via structure.

Through the above single-sided via structure, electrode 210 of electronic component 200 is electrically connected to conductive layer 120 on insulation layer 102 by via conductor (321b), and electrode 220 of electronic component 200 is electrically connected to conductive layer 120 on insulation layer 102 by via conductor (322b). Since electrical connections are formed in inner layers in such a structure, it is advantageous for miniaturization.

At least one of via conductors (313b, 323b, 333b, 343b) is positioned directly on through-hole conductor (300b) (in direction Z), and adjacent conductors make contact with each other. Accordingly, a through-hole conductor and a via conductor, or adjacent via conductors, are electrically connected to each other. In the present embodiment, via conductors (313b, 323b, 333b, 343b) and through-hole conductor (300b) are each a filled conductor, and they are stacked in direction Z. Such a stacked structure is advantageous for miniaturization.

Conductive layer 301 and conductive layer 110 are electrically connected to each other by via conductor (313b), and conductive layer 302 and conductive layer 120 are electrically connected to each other by via conductor (323b). Also, conductive layer 110 and conductive layer 130 are electrically connected to each other by via conductor (333b), and conductive layer 120 and conductive layer 140 are electrically connected to each other by via conductor (343b).

Solder resists (11, 12) are formed respectively on conductive layers (130, 140) (each an outermost conductive layer). However, opening portions (11a, 12a) are formed respectively in solder resists (11, 12). Thus, a predetermined spot (spot corresponding to opening portion (11a)) of conductive layer 130 is exposed without being covered by solder resist 11, and becomes pad (P11). Also, a predetermined spot (spot corresponding to opening portion (12a)) of conductive layer 140 becomes pad (P12). Pad (P11) becomes an external connection terminal for electrical connection with another wiring board, for example, and pad (P12) becomes an external connection terminal for mounting an electronic component, for example. However, those are not the only options, and pads (P11, P12) may be used for any other purposes.

Wiring board 10 of the present embodiment has pads (P11, P12) (external connection terminals) directly on electronic component 200 (in direction Z). Wiring board 10 also has pads (P11, P12) (external connection terminals) directly on substrate 100 (in direction Z). Pads (P11, P12) have anticorrosion layers made of Ni/Au film, for example, on their surfaces. Anticorrosion layers may be formed by electrolytic plating, sputtering or the like. Anticorrosion layers made of organic protection film may also be formed by performing an OSP treatment. Anticorrosion layers are not always required, and may be omitted unless necessary.

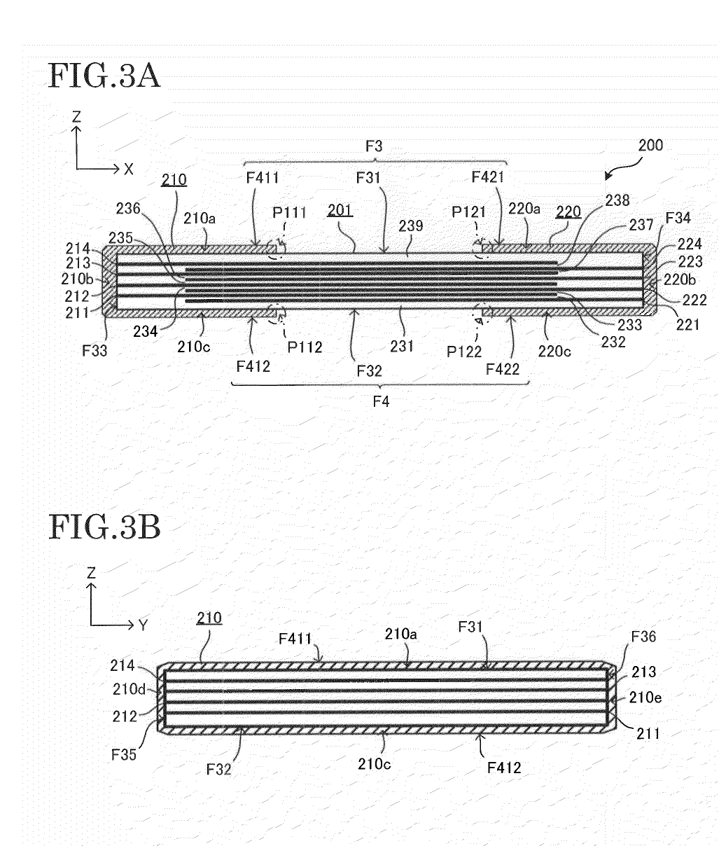

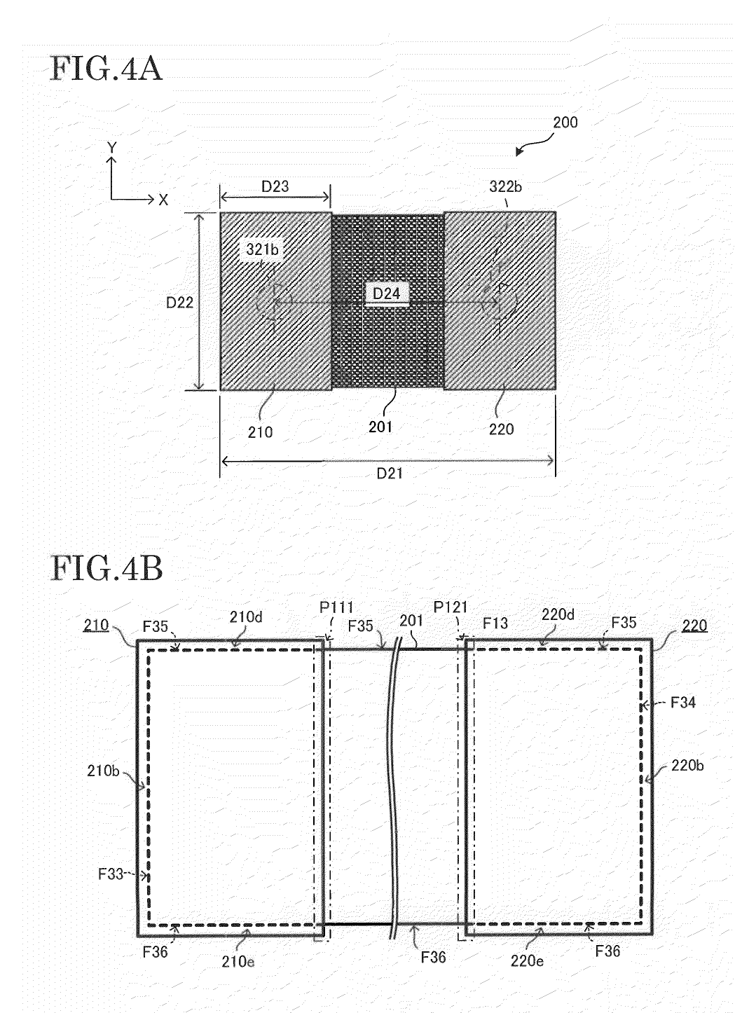

In the following, the structure of electronic component 200 (chip capacitor) to be built into wiring board 10 of the present embodiment is described with reference to FIGS. 3A˜4B. FIG. 3A is a view showing a first cross-sectional shape (X-Z cross section) of electronic component 200. FIG. 3B is a view showing a second cross-sectional shape (Y-Z cross section) of electronic component 200. FIG. 4A is a plan view of electronic component 200. FIG. 4B is a view showing electrodes formed on side surfaces of body 201 of electronic component 200.

Electronic component 200 is a chip-type MLCC (multilayer ceramic capacitor) as shown in FIGS. 3A˜4B, for example. The capacitance of the capacitor is 0.22 μF, for example.

Electronic component 200 has body 201 and electrodes (210, 220) (first side electrode and its opposing second side electrode). Body 201 is formed with multiple dielectric layers (231˜239) and multiple conductive layers (211˜214, 221˜224) (each an inner electrode) which are alternately laminated as shown in FIG. 3A. Dielectric layers (231˜239) are each made of ceramic, for example. Body 201 has first main surface (F31) and its opposing second main surface (F32) along direction Z; first side surface (F33) and its opposing second side surface (F34) along direction X; and third side surface (F35) and its opposing fourth side surface (F36) along direction Y. First through fourth side surfaces (F33˜F36) each connect first main surface (F31) and second main surface (F32).

Electronic component 200 has a pair of side electrodes (electrodes (210, 220)) at both of its end portions. Electrodes (210, 220) each have a cross-sectional U-shape (X-Z cross section) as shown in FIG. 3A. In the present embodiment, as shown in FIGS. 3A and 4B, electrode 210 is formed on first main surface (F31), on second main surface (F32), on first side surface (F33), on third side surface (F35) and on fourth side surface (F36) of body 201; and electrode 220 is formed on first main surface (F31), on second main surface (F32), on second side surface (F34), on third side surface (F35) and on fourth side surface (F36) of body 201.

In the following, portions of electrode 210 formed on first side surface (F33), on third side surface (F35) and on fourth side surface (F36) are referred to respectively as first side portion (210b), third side portion (210d) and fourth side portion (210e) (see FIG. 4B). Portions of electrode 220 formed on second side surface (F34), on third side surface (F35) and on fourth side surface (F36) are referred to respectively as second side portion (220b), third side portion (220d) and fourth side portion (220e) (see FIG. 4B). In addition, portions of electrodes (210, 220) formed on first main surface (F31) are referred to as upper portions (210a, 220a), and portions formed on second main surface (F32) are referred to as lower portions (210c, 220c) (see FIG. 3A).

Electrode 210 is formed with first side portion (210b) which covers entire first side surface (F33) of body 201, along with upper portion (210a), lower portion (210c), third side portion (210d) and fourth side portion (210e) respectively covering part of first main surface (F31) of body 201, part of second main surface (F32), part of third side surface (F35) and part of fourth side surface (F36). Also, electrode 220 is formed with second side portion (220b) which covers entire second side surface (F34) of body 201, along with upper portion (220a), lower portion (220c), third side portion (220d) and fourth side portion (220e) respectively covering part of first main surface (F31) of body 201, part of second main surface (F32), part of third side surface (F35) and part of fourth side surface (F36).

In the following, the upper surface of upper portion (210a) of electrode 210 is referred to as first electrode surface (F411), the upper surface of upper portion (220a) of electrode 220 as first electrode surface (F421), the upper surface of lower portion (210c) of electrode 210 as second electrode surface (F412), and the upper surface of lower portion (220c) of electrode 220 as second electrode surface (F422). As shown in FIG. 3A, third surface (F3) of electronic component 200 is formed with first electrode surface (F411), first main surface (F31) of body 201, and first electrode surface (F421). Fourth surface (F4) of electronic component 200 is formed with second electrode surface (F412), second main surface (F32) of body 201, and second electrode surface (F422).

In the present embodiment, upper portion (210a), first side portion (210b), third side portion (210d), fourth side portion (210e) and lower portion (210c) are formed to be integrated with each other in electrode 210; and upper portion (220a), second side portion (220b), third side portion (220d), fourth side portion (220e) and lower portion (220c) are formed to be integrated with each other in electrode 220. Either end of body 201 is covered by electrode 210 or 220 from second main surface (F32) to side surfaces (first side surface (F33), second side surface (F34), third side surface (F35), fourth side surface (F36)) to first main surface (F31). Conductive layers (211˜214) (each an inner electrode) are connected to first side portion (210b) (part of electrode 210), and conductive layers (221˜224) (each an inner electrode) are connected to second side portion (220b) (part of electrode 220).

Electrodes (210, 220) are positioned at both end portions of electronic component 200. The central portion of body 201 positioned between electrode 210 and electrode 220, as shown in FIG. 3A, is not covered by electrodes (210, 220), and first main surface (F31) and second main surface (F32) of body 201 (in particular, dielectric layers (231, 239)) are exposed. In the following, an end portion of electrode 210 positioned on first main surface (F31) of body 201 is referred to as end portion (P111), an end portion of electrode 220 positioned on first main surface (F31) of body 201 as end portion (P121), an end portion of electrode 210 positioned on second main surface (F32) of body 201 as end portion (P112), and an end portion of electrode 220 positioned on second main surface (F32) of body 201 as end portion (P122). The position of end portion (P111) on the X-Y plane (X coordinate and Y coordinate) is the same as that of end portion (P112), and the position of end portion (P121) on the X-Y plane (X coordinate and Y coordinate) is the same as that of end portion (P122).

FIG. 5A is a view in which electronic component 200 is accommodated in cavity (R10) of the core section.

In wiring board 10 of the present embodiment, the opening shapes on both ends of cavity (R10) (first-surface (F1) side and second-surface (F2) side) are each rectangular as shown in FIG. 5A. Electrode 210 is positive (+), for example, and electrode 220 is negative (−), for example. Electrode 210 of electronic component 200 is electrically connected to power source through a die, for example. Also, electrode 220 of electronic component 200 is electrically connected to ground through via conductor (322b) or the like, for example.

As shown in FIGS. 3A˜4B, electronic component 200 of the present embodiment has a symmetrical structure in direction X on one end (the electrode 210 side, for example) and the other end (the electrode 220 side, for example). Thus, even if the polarities of electrode 210 and electrode 220 are reversed, electronic component 200 operates. Therefore, when electronic component 200 is positioned in cavity (R10) in wiring board 10 of the present embodiment, there is no need to check the direction of electronic component 200.

As shown in FIG. 5A and FIG. 5B (partially enlarged view of FIG. 5A), conductive patterns (301a, 301b) included in conductive layer 301 are each formed linearly and have a planar U-shape (X-Y plane). Namely, conductive patterns (301a, 301b) each have a U-shaped linear pattern. Conductive patterns (301a, 301b) are positioned along direction X to face each other (U-shaped openings facing each other), for example. In the following, one end (the Y1 side, for example) of linear conductive pattern (301a) is referred to as end portion (P311), and the other (the Y2 side, for example) as end portion (P312). Also, one end (the Y1 side, for example) of linear conductive pattern (301b) is referred to as end portion (P321), and the other (the Y2 side, for example) as end portion (P322).

In the present embodiment, linear conductive pattern (301a) and linear conductive pattern (301b) form a ring-shaped conductive pattern with two breaks (between end portion (P311) and end portion (P321) and between end portion (P312) and end portion (P322), for example). The ring-shaped conductive pattern surrounds the first-surface (F1) side opening (hereinafter referred to as the first opening) of cavity (R10). Conductive patterns (301a, 301b) are each formed along the shape of the first opening (rectangle) of cavity (R10). Namely, the angles of the U shape are 90 degrees. Two U-shaped linear patterns (conductive patterns (301a, 301b)) are positioned to face each other so that they surround the first opening of cavity (R10).

Conductive patterns (301a, 301b) are shaped to be symmetrical relative to cavity (R10). More specifically, conductive patterns (301a, 301b) are shaped to be symmetrical to a line that passes through the centers of two sides (a side on the Y1 side, and a side on the Y2 side) of cavity (R10) in direction X (hereinafter referred to as center line (L0)). In the present embodiment, the width of conductive pattern (301a) is the same as the width of conductive pattern (301b). Also, in the present embodiment, direction X corresponds to the direction in which electrodes (210, 220) of electronic component 200 are arrayed, and conductive patterns (301a, 301b) are also arrayed in direction X. In addition, the direction of center line (L0) corresponds to direction Y.

Conductive pattern (301a) is positioned near electrode 210 (first side electrode) of electronic component 200, and conductive pattern (301b) is positioned near electrode 220 (second side electrode) of electronic component 200. Specifically, conductive pattern (301a) (first conductive pattern) has a planar U-shape (X-Y plane) that faces three sides of electrode 210 (for example, first side portion (210b), third side portion (210d) and fourth side portion (210e) shown in FIG. 4B), and conductive pattern (301b) has a planar U-shape (X-Y plane) that faces three sides of electrode 220 (for example, second side portion (220b), third side portion (220d) and fourth side portion (220e) shown in FIG. 4B).

Conductive pattern (301a) and conductive pattern (301b) are positioned with a gap in between (a gap with distance (D30) shown in FIG. 5B). Accordingly, conductive pattern (301a) and conductive pattern (301b) are insulated from each other.

In the present embodiment, conductive patterns (301a, 301b, 302a, 302b) are not electrically connected to other conductive patterns (conductive pattern 301c or 302c or the like) in conductive layer 301 or 302, nor do they make interlayer connections. Accordingly, conductive patterns (301a, 301b, 302a, 302b) each do not form a circuit, and are electrically independent. Thus, if electrode 210 or 220 of electronic component 200 and conductive patterns (301a, 301b, 302a, 302b) make electrical contact with each other for any reason, electronic component 200 seldom experiences operational abnormalities (or abnormal electrical characteristics).

In the present embodiment, at least part of conductive layer 301 (including conductive patterns (301a, 301b)) is formed on the same plane (F101) (at the same height) as at least part of electrodes (210, 220) (in particular, upper portions (210a, 220a)) of electronic component 200. Also, at least part of conductive layer 302 is formed on the same plane (F102) (at the same height) as at least part of electrodes (210, 220) (in particular, lower portions (210c, 220c)) of electronic component 200. In such a structure, when electronic component 200 is positioned near wall surfaces of cavity (R10), electrodes (210, 220) of electronic component 200 and conductive layer 301 or 302 (especially, conductive patterns (301a, 301b, 302a, 302b) positioned on the peripheral portions of cavity (R10)) tend to be electrically connected. However, since conductive patterns (301a, 301b, 302a, 302b) are each electrically independent in wiring board 10 of the present embodiment, even if those conductive patterns and electrode 210 or 220 of electronic component 200 make electrical contact with each other, electronic component 200 seldom experiences operational abnormalities (or abnormal electrical characteristics).

In the present embodiment, conductive pattern (301a) is formed on a first peripheral portion of cavity (R10) with which electrode 220 of electronic component 200 never makes contact, and conductive pattern (301b) is formed on a second peripheral portion of cavity (R10) with which electrode 210 of electronic component 200 never makes contact.

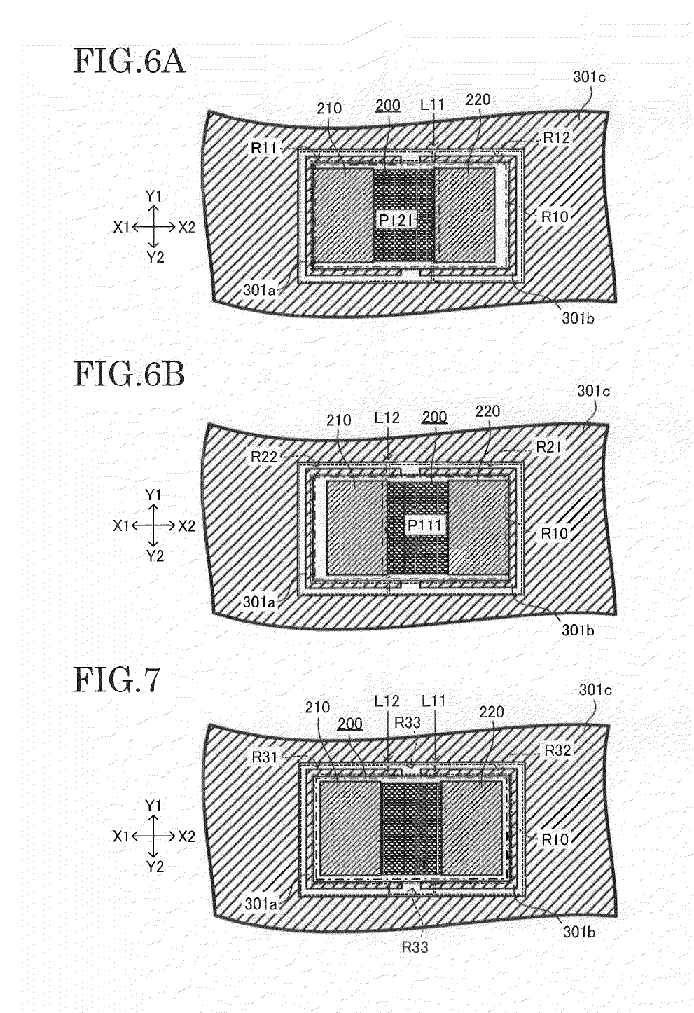

Specifically, if at least there is a clearance between cavity (R10) and electronic component 200, it is possible for electronic component 200 to shift within cavity (R10). For example, as shown in FIG. 6A, electronic component 200 can shift toward the X1 side until electrode 210 makes contact with a wall surface of cavity (R10). End portion (P121) of electrode 220 cannot shift to the X1 side beyond such location (L11) (X coordinate). Namely, electrode 220 of electronic component 200 cannot make contact with the peripheral portion of cavity (R10) positioned on the X1 side beyond location (L11) (hereinafter referred to as first peripheral portion (R11)), but can make contact with the peripheral portion of cavity (R10) positioned on the X2 side from location (L11) (hereinafter referred to as third peripheral portion (R12)).

Also, as shown in FIG. 6B, for example, electronic component 200 can shift toward the X2 side until electrode 220 makes contact with a wall surface of cavity (R10). End portion (P111) of electrode 210 cannot shift to the X2 side beyond such location (L12) (X coordinate). Namely, electrode 210 of electronic component 200 cannot make contact with the peripheral portion of cavity (R10) positioned on the X2 side beyond location (L12) (hereinafter referred to as second peripheral portion (R21)), but can make contact with the peripheral portion of cavity (R10) positioned on the X1 side from location (L12) (hereinafter referred to as fourth peripheral portion (R22)).

FIG. 7 shows the following: fifth peripheral portion (R31) with which electrode 210 of electronic component 200 can make contact but with which electrode 220 never makes contact; sixth peripheral portion (R32) with which electrode 220 of electronic component 200 can make contact but with which electrode 210 never makes contact; and seventh peripheral portion (R33) with which neither electrode 210 nor electrode 220 of electronic component 200 ever makes contact. First peripheral portion (R11) is made up of fifth peripheral portion (R31) and seventh peripheral portion (R33). Second peripheral portion (R21) is made up of sixth peripheral portion (R32) and seventh peripheral portion (R33).

In the present embodiment, entire conductive pattern (301a) is formed on first peripheral portion (R11) of cavity (R10) (see FIG. 6A). Specifically, conductive pattern (301a) is formed on entire fifth peripheral portion (R31). Also, part of conductive pattern (301a) is formed on seventh peripheral portion (R33) (see FIG. 7).

Also, in the present embodiment, entire conductive pattern (301b) is formed on second peripheral portion (R21) of cavity (R10) (see FIG. 6B). Specifically, conductive pattern (301b) is formed on entire sixth peripheral portion (R32). Also, part of conductive pattern (301b) is formed on seventh peripheral portion (R33) (see FIG. 7).

According to the above structure, electrode 210 and electrode 220 of electronic component 200 seldom short circuit (unwanted electrical connection) in wiring board 10 of the present embodiment. Specifically, as shown in FIG. 8, for example, when ring-shaped conductive pattern 3000 which does not have a break is substituted with conductive patterns (301a, 301b) in wiring board 10 of the present embodiment, electrodes (210, 220) of electronic component 200 may each make electrical contact with conductive pattern 3000 when electronic component 200 shifts within cavity (R10) and touches wall surfaces or the like of cavity (R10). Accordingly, electrodes (210, 220) may easily short circuit through conductive pattern 3000.

For that matter, conductive pattern (301a) and conductive pattern (301b) are electrically insulated from each other in wiring board 10 of the present embodiment. Thus, electrode 220 of electronic component 200 cannot make contact with first peripheral portion (R11) of cavity (R10) where conductive pattern (301a) is formed, and electrode 210 of electronic component 200 cannot make contact with second peripheral portion (R21) of cavity (R10) where conductive pattern (301b) is formed. Accordingly, only electrode 210 can make contact with first peripheral portion (R11), and there is no occasion that both electrode 210 and electrode 220 make contact with first peripheral portion (R11). Also, only electrode 220 can make contact with second peripheral portion (R21), and there is no occasion that both electrode 210 and electrode 220 make contact with second peripheral portion (R21). Accordingly, as shown in FIG. 9, no matter where electronic component 200 is positioned (X, Y coordinates) in cavity (R10), neither conductive pattern (301a) on first peripheral portion (R11) nor conductive pattern (301b) on second peripheral portion (R21) is formed to cover both vicinities of electrode 210 and electrode 220. Therefore, even if electronic component 200 shifts freely within cavity (R10), it is thought that electrode 210 and electrode 220 seldom short circuit.

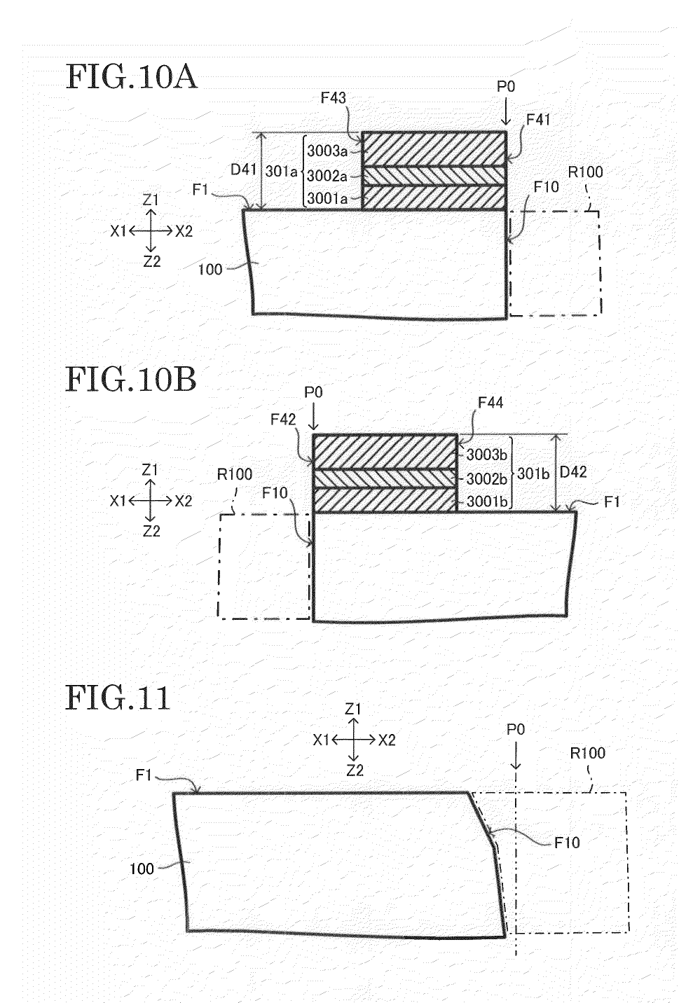

As shown in FIG. 10A, conductive pattern (301a) has side surface (F41) on the opening section (R100) side (or cavity (R10) side), and its opposing side surface (F43). Also, as shown in FIG. 10B, conductive pattern (301b) has side surface (F42) on the opening section (R100) side (or cavity (R10) side), and on its opposing side surface (F44). Side surfaces (F41˜F44) are each substantially perpendicular to first surface (F1) of substrate 100. However, that is not the only option, and the angle of each side surface to first surface (F1) of substrate 100 may be acute or obtuse, for example.

In the present embodiment, the position (X coordinate, for example) of side surface (F41) (Y-Z plane, for example) of conductive pattern (301a) substantially corresponds to the position of wall surface (F10) of opening section (R100) as shown in FIG. 10A. Also, the position (X coordinate, for example) of side surface (F42) (Y-Z plane, for example) of conductive pattern (301b) substantially corresponds to the position of wall surface (F10) of opening section (R100) as shown in FIG. 10B. Accordingly, side surfaces (F41, F42) are each made flush with wall surface (F10) (on the same plane) of opening section (R100). In particular, conductive patterns (301a, 301b) are each formed on substrate 100 before opening section (R100) is formed in substrate 100. At that time, side surfaces (F41, F42) of those conductive patterns are each positioned where wall surface (F10) of opening section (R100) is to be formed (for example, designed location (P0) shown in FIGS. 10A and 10B). Then, while a laser is irradiated on conductive patterns (301a, 301b), the laser is also irradiated on their inner portions (a region of substrate 100 surrounded by conductive patterns (301a, 301b)) so that opening section (R100) is formed in substrate 100. In doing so, wall surfaces (F10) of opening section (R100) (wall surfaces of a cavity) are made into cut surfaces contiguous to side surfaces (F41, F42) of the conductive patterns.

In wiring board 10 of the present embodiment, conductive layer 301 includes conductive patterns (301a, 301b) surrounding the first opening of cavity (R10). Accordingly, processing accuracy when forming a cavity is thought to be enhanced. The reasons are described below.

For example, as shown in FIG. 11, if a conductive layer on substrate 100 does not have conductive patterns in portions corresponding to the periphery of opening section (R100) (cavity), when a laser is used, for example, to process substrate 100 (such as resin insulation layer), the processed amount increases as processing goes deeper, causing the cut surface corresponding to wall surface (F10) of opening section (R100) to taper. In addition, if a high intensity laser is irradiated on substrate 100, surrounding resin (especially outside designed location (P0)) tends to be removed as well. Thus, positions of wall surfaces (F10) tend to shift from designed location (P0) (X coordinate, for example), making it harder to form opening section (R100) (cavity) to have measurements as originally designed.

For that matter, in wiring board 10 of the present embodiment, conductive layer 301 includes conductive patterns (301a, 301b) surrounding the first opening of cavity (R10). Thus, opening section (R100) is formed in substrate 100 by irradiating a laser on conductive patterns (301a, 301b), and by also irradiating the laser on their inner portions (a region of substrate 100 surrounded by conductive patterns (301a, 301b)). In such a case, if a high intensity laser is irradiated on substrate 100, since substrate 100 is protected by conductive patterns (301a, 301b), portions of substrate 100 outside designed location (P0) are less likely to be processed. Also, by irradiating a high intensity laser, cut surfaces tend not to taper. As a result, the processing accuracy of forming a cavity is enhanced, making it easier to form cavity (R10) to have measurements as originally designed. In the present embodiment, conductive patterns (301a, 301b) are each made of a material (such as metal) that is less likely to be processed by a laser than substrate 100 (such as resin).

In addition, enhancing processing accuracy when forming a cavity makes it easier to reduce the clearance between cavity (R10) and electronic component 200 positioned inside. In particular, for example, a clearance (“width (D11)-width (D21)” using measurements shown in FIG. 4A or 5A) between cavity (R10) and electronic component 200 can be set at 60 μm or less in the direction in which electrode 210 and electrode 220 are arrayed (direction X, for example).

Also, by reducing the clearance between cavity (R10) and electronic component 200, positional shifting is suppressed (and subsequent hole breakout) between electrodes (210, 220) of electronic component 200 and via conductors (321b, 322b) connected to the electrodes.

Also, when cavity (R10) is made smaller, a wiring region on substrate 100 is enlarged. Especially, since conductive patterns (301a, 301b) are formed to be linear, it is easier to secure a wiring region outside conductive patterns (301a, 301b) (a side farther from cavity (R10)).

Also, when cavity (R10) is made smaller, the strength of substrate 100 is easier to secure. As a result, substrate 100 becomes less likely to warp.

When a cavity is formed by etching or the like other than using a laser, processing accuracy is thought to be enhanced because of conductive patterns (301a, 301b), compared with a wiring board where nothing is formed in surrounding portions (peripheral portions) of a cavity.

In the present embodiment, conductive pattern (301a) is made up of first layer (3001a) (lower layer), second layer (3002a) (middle layer) and third layer (3003a) (upper layer) as shown in FIG. 10A. Also, conductive pattern (301b) is made up of first layer (3001b) (lower layer), second layer (3002b) (middle layer) and third layer (3003b) (upper layer) as shown in FIG. 10B. First layers (3001a, 3001b) are each made of copper foil, for example. Second layers (3002a, 3002b) are each made of electroless copper plating, for example. Third layers (3003a, 3003b) are each made of electrolytic copper plating, for example. In the present embodiment, thickness (D41) of conductive pattern (301a) is the same as thickness (D42) of conductive pattern (301b).

In the present embodiment, conductive pattern (301b) has the same layer structure (including the thickness of each layer and material) as conductive pattern (301a). In particular, since conductive patterns included in conductive layer 301 are all formed at the same time, all the conductive patterns included in conductive layer 301 (conductive patterns (301a, 301b, 301c), for example) have the same layer structure as each other. In the present embodiment, all the conductive patterns included in conductive layer 301 are each made of metal foil formed on substrate 100 and plated film on the metal foil.

In the present embodiment, conductive pattern (301a) and conductive pattern (301b) have the same cross-sectional structure (X-Z cross section) (see FIGS. 10A and 10B). However, that is not the only option, and conductive pattern (301a) and conductive pattern (301b) may have a different cross-sectional structure from each other.

In the present embodiment, conductive layer 301 includes other conductive patterns in addition to conductive patterns (301a, 301b). In particular, planar conductive pattern (301c) is formed outside conductive patterns (301a, 301b) (a side farther from cavity (R10)).

In the present embodiment, planar conductive pattern (301c) is formed around cavity (R10) to keep a predetermined distance from cavity (R10) in four directions (for example, distance (D13) shown in FIG. 5B). Distance (D13) is approximately 70 μm, for example. However, that is not the only option, and the distances between cavity (R10) and conductive pattern (301c) formed in four directions around cavity (R10) may vary.

Among the other conductive patterns included in conductive layer 301 (conductive patterns other than conductive patterns (301a, 301b)), the distance to cavity (R10) from a conductive pattern closest to cavity (R10) is preferred to be 70 μm or less. By reducing the distance between conductive patterns (301a, 301b) and a conductive pattern outside them (wiring pattern, for example), the wiring region is enlarged. As a result, it is easier to form more wiring.

Planar shapes (X-Y plane) and positions (X coordinates, Y coordinates) of linear conductive patterns (302a, 302b) and planar conductive pattern (302c) included in conductive layer 302 are the same as those of conductive patterns (301a, 301b, 301c) included in conductive layer 301, for example. Namely, a ring-shaped conductive pattern with breaks is formed with conductive patterns (302a, 302b), and the ring-shaped conductive pattern surrounds the opening on the second-surface (F2) side of cavity (R10) (hereinafter referred to as the second opening). When conductive layer 302 includes such conductive patterns (302a, 302b, 302c), it is thought that processing accuracy is enhanced in each processing conducted from both surfaces of substrate 100 to form cavity (R10) (such as laser processing).

In the following, preferred examples of materials for wiring board 10 of the present embodiment are shown.

Substrate 100 is made of resin containing core material in the present embodiment. Specifically, substrate 100 is made by impregnating glass cloth (core material) with epoxy resin (hereinafter referred to as glass epoxy), for example. The thermal expansion coefficient of core material is lower than that of the main material (epoxy resin in the present embodiment). As for core material, for example, glass fiber (such as glass cloth or glass non-woven fabric), aramid fiber (such as aramid non-woven fabric), or inorganic material such as silica filler is considered preferable. However, basically, any material may be selected for substrate 100. For example, substrate 100 may be made of resin that does not contain core material. Also, polyester resin, bismaleimide triazine resin (BT resin), imide resin (polyimide), phenol resin, allyl polyphenylene ether resin (A-PPE resin) or the like may be used instead of epoxy resin. Substrate 100 may be formed with multiple layers of different materials.

In the present embodiment, insulation layers (101, 102, 103, 104) are each made by impregnating core material with resin. Specifically, insulation layers (101, 102, 103, 104) are each made of glass epoxy, for example.

In the present embodiment, insulation layers (101, 102) are each made of resin containing core material. Accordingly, recesses are less likely to be formed in insulation layers (101, 102), suppressing line breakage of conductive patterns formed on insulation layers (101, 102). In addition, electronic component 200 is suppressed from shifting in direction Z, and positional shifting of electronic component 200 seldom occurs in direction Z. However, impact on the core section may increase during pressing procedures.

However, the above settings are not the only options. For example, insulation layers (101, 102, 103, 104) may be made of resin that does not contain core material. Basically, the material for insulation layers (101, 102, 103, 104) is not limited to a specific kind. For example, polyester resin, bismaleimide triazine resin (BT resin), imide resin (polyimide), phenol resin, allyl polyphenylene ether resin (A-PPE resin) or the like may be used instead of epoxy resin. Each insulation layer may be formed with multiple layers of different materials.

In the present embodiment, via conductors (313b, 321b, 322b, 323b, 333b, 343b) are each made of copper plating, for example. Via conductors are each shaped to be a tapered column (truncated cone) that tapers with a diameter increasing from the core section toward their respective upper layers, for example. However, that is not the only option, and via conductors may be shaped in any other way.

Conductive layers (110, 120, 130, 140) are each made of copper foil (lower layer) and copper plating (upper layer), for example. Conductive layers (110, 120, 130, 140) each include wiring that forms an electrical circuit, a land, a planar conductive pattern to improve the strength of wiring board 10, and the like, for example.

The material for each conductive layer and each via conductor is selected freely as long as it is conductive; it may be metallic or non-metallic. Each conductive layer and each via conductor may be formed with multiple layers of different materials.

In the following, preferred examples of measurements in wiring board 10 of the present embodiment are shown.

In FIG. 4A, width (D21) in a longitudinal direction (direction X) of electronic component 200 is approximately 1000 μm, for example, and width (D22) in a lateral direction (direction Y) of electronic component 200 is approximately 500 μm, for example. Width (D23) of upper portion (210a) or lower portion (210c) of electrode 210 is approximately 230 μm, for example.

The areas of upper portion (210a) and lower portion (210c) of electrode 210 (external electrode on first main surface (F31) and on second main surface (F32)) are each approximately 0.115 mm² (=230 μm×500 μm), for example. The areas of upper portion (210a) and lower portion (210c) of electrode 210 (external electrode on first main surface (F31) and on second main surface (F32)) are each preferred to be 0.2 mm² or smaller.

In the present embodiment, the measurements of electrode 220 are the same as those of electrode 210. However, that is not the only option, and electrode 210 and electrode 220 may have different measurements from each other.

Pitch (D24) of via conductors (321b, 322b) is approximately 770 μm, for example, in FIG. 4A.

In FIG. 5A, width (D11) in a longitudinal direction (direction X) of cavity (R10) is approximately 1040 μm, for example, and width (D12) in a lateral direction (direction Y) of cavity (R10) is approximately 540 μm, for example.

In FIG. 5A, the clearance between electronic component 200 and cavity (R10) is approximately 40 μm (=width (D11)−width (D21)), for example, in a longitudinal direction (direction X) and approximately 40 μm (=width (D12)−width (D22)), for example, in a lateral direction (direction Y).

In FIG. 5A, widths (D31, D32) of conductive pattern (301a) in direction X (Y1 side, Y2 side) are each approximately 495 μm, for example. In the present embodiment, width (D31) is the same as width (D32). However, that is not the only option, and width (D31) and width (D32) may have different measurements from each other.

In FIG. 5B, widths (D33, D34) of conductive pattern (301a) (width of line Y, width of line X) are each approximately 25 μm, for example. Conductive pattern (301a) or (301b) is preferred to have a width of 30 μm or smaller (the minimum width if widths vary). By setting so, a wiring region is easier to secure outside conductive pattern (301a) or (301b). In the present embodiment, width (D33) is the same as width (D34). However, that is not the only option, and measurements of width (D33) and width (D34) may be different, for example.

In the present embodiment, conductive pattern (301b) has the same measurement as conductive pattern (301a). However, that is not the only option, and measurements in conductive pattern (301a) and conductive pattern (301b) may be different from each other.

The distance between conductive pattern (301a) and conductive pattern (301b) (distance (D30) shown in FIG. 5B), in particular the distance between end portion (P311) and end portion (P321) and the distance between end portion (P312) and end portion (P322), is approximately 50 μm (=width (D11)−width (D31)×2), for example. Conductive pattern (301a) and conductive pattern (301b) are insulated from each other because of that space. In the present embodiment, the distance between end portion (P311) and end portion (P321) is the same as the distance between end portion (P312) and end portion (P322). However, that is not the only option, and those distances may have different measurements from each other.

The sum of the lengths of conductive pattern (301a) and conductive pattern (301b) surrounding the first opening of cavity (R10) is approximately 3060 μm (=2×(width (D12)+width (D31)+width (D32)), for example. In addition, the entire circumference of the first opening of cavity (R10) is approximately 3160 μm (=width (D11)×2+width (D12)×2), for example. The sum of the lengths of conductive pattern (301a) and conductive pattern (301b) corresponds to approximately 97% (=3060 μm/3160 μm) of the entire circumference of the first opening of cavity (R10). The sum of the lengths of conductive pattern (301a) and conductive pattern (301b) surrounding the first opening of cavity (R10) is preferred to be 85% or greater of the entire circumference of the first opening of cavity (R10). When 85% or greater of the entire circumference of the first opening of cavity (R10) is surrounded, processing accuracy is enhanced on substantially the entire cavity (R10).

The thickness of substrate 100 is approximately 150 μm, for example. The thickness of insulation layer 101 and the thickness of insulation layer 102 are each approximately 25 μm, for example. In the present embodiment, the thickness of insulation layer 101 is the same as the thickness of insulation layer 102, for example. However, that is not the only option, and they may be different from each other.

The thickness of insulation layer 103 and the thickness of insulation layer 104 are each approximately 25 μm, for example. In the present embodiment, the thickness of insulation layer 103 is the same as the thickness of insulation layer 104, for example. However, that is not the only option, and they may be different from each other.

The thickness of each insulation layer above is measured by setting the upper surface of their respective lower insulation layers (core substrate for a lower buildup section) as the base (zero). Namely, for example, the thickness of insulation layer 101 and the thickness of insulation layer 102 each correspond to the thickness that includes insulator (101a).

The thickness of conductive layer 301 (including conductive patterns (301a, 301b, 301c)) and the thickness of conductive layer 302 (including conductive patterns (302a, 302b, 302c)) are each approximately 15 μm, for example. In the present embodiment, all the conductive patterns included in conductive layer 301 have the same thickness. Also, all the conductive patterns included in conductive layer 302 have the same thickness. In addition, the thickness of conductive layer 301 is the same as the thickness of conductive layer 302. However, that is not the only option, and they may have different thicknesses from each other.

The thickness of conductive layer 110, the thickness of conductive layer 120, the thickness of conductive layer 130 and the thickness of conductive layer 140 are each approximately 15 μm, for example. The thickness of conductive layer 110, the thickness of conductive layer 120, the thickness of conductive layer 130 and the thickness of conductive layer 140 are each the same, for example. However, that is not the only option, and they may be different from each other.

The thickness of electronic component 200 including external electrodes (electrodes (210, 220)) is preferred to be smaller than the thickness of cavity (R10). In so setting, electronic component 200 is accommodated entirely in cavity (R10), and impact is less likely to be exerted on electronic component 200.

In wiring board 10 of the present embodiment, upper surfaces of conductive layers (301, 302) are roughened, while upper surfaces of electrodes (210, 220) (upper surfaces of upper portions (210a, 220a) and upper surfaces of lower portions (210c, 220c)) are not roughened (see FIG. 2). Because of such a difference in roughening treatment, the 10-point average roughness (Rzjis) of upper surfaces of electrodes (210, 220) is smaller than any 10-point average roughness (Rzjis) of the upper surface of conductive layer 301 and the upper surface of conductive layer 302. As a result, it is easier to achieve a high degree of adhesiveness between conductive layer 301 and insulation layer 101 and between conductive layer 302 and insulation layer 102. Also, in the present embodiment, the upper surfaces of conductive layers (110, 120, 130, 140) are each roughened with substantially the same degree of roughness as that of the upper surface of conductive layer 301 or 302. Accordingly, adhesiveness is improved between those upper surfaces and their respective insulation layers or the like formed thereon.

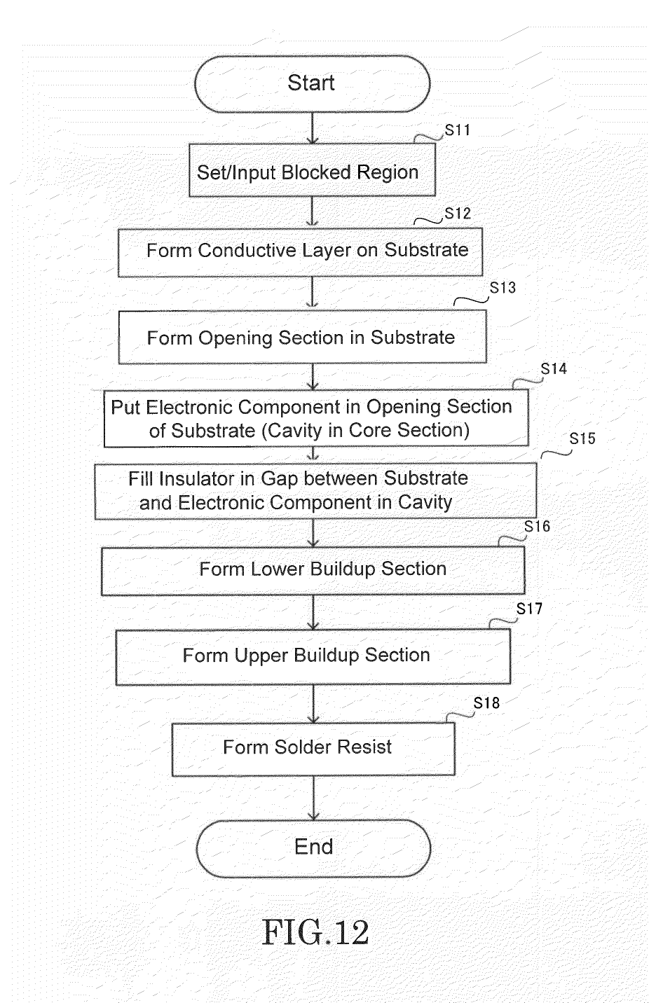

The following is a description of a method for manufacturing wiring board 10 according to the present embodiment. FIG. 12 is a flowchart schematically showing the contents and order of a method for manufacturing wiring board 10 according to the present embodiment. In the manufacturing method of the present embodiment, apparatuses used in each step are controlled by a computer (hereinafter referred to as a control section).

In step (S11) of FIG. 12, a blocked region is set around cavity (R10) on first surface (F1) of substrate 100, where no conductive pattern except for conductive patterns (301a, 301b) is formed (hereinafter referred to as the first blocked region), and the first blocked region is input into the control section. Also, another blocked region is set around cavity (R10) on second surface (F2) of substrate 100, where no conductive pattern except for conductive patterns (302a, 302b) is formed (hereinafter referred to as the second blocked region), and the second blocked region is input into the control section. The first blocked region and the second blocked region are each preferred to be in a range within 70 μm or smaller from cavity (R10). Namely, distance (D13) shown in FIG. 5B is preferred to be 70 μm or less. According to such a manufacturing method, a wiring region is more easily secured outside conductive patterns (301a, 301b, 302a, 302b) (a side farther from cavity (R10)). In the present embodiment, the above control section (computer) is used in an apparatus for forming conductive layers.

In step (S12) of FIG. 12, a core substrate of wiring board 10 is prepared and conductive layers are formed on both of its surfaces.

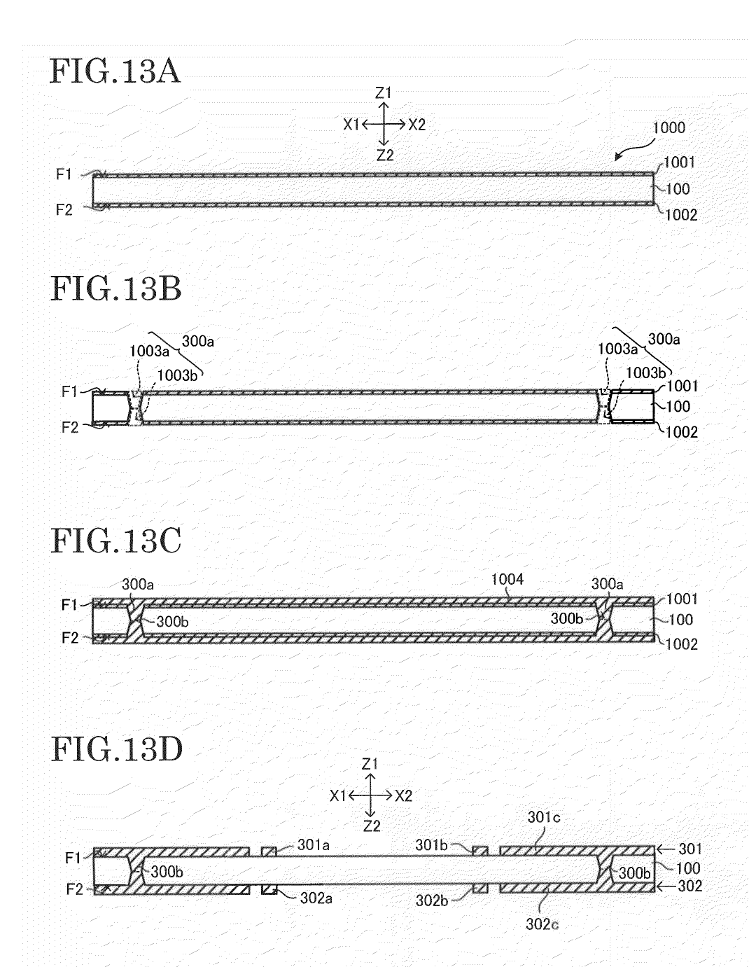

Specifically, as shown in FIG. 13A, double-sided copper-clad laminate 1000 is prepared as a starting material. Double-sided copper-clad laminate 1000 is formed with substrate 100 (core substrate) having first surface (F1) and its opposing second surface (F2), metal foil 1001 (copper foil, for example) formed on first surface (F1) of substrate 100, and metal foil 1002 (copper foil, for example) formed on second surface (F2) of substrate 100. In the present embodiment, substrate 100 is made of completely cured (C-stage) glass epoxy at this stage.

As shown in FIG. 13B, using a CO₂ laser, for example, hole (1003a) is formed by irradiating the laser on double-sided copper-clad laminate 1000 from the first-surface (F1) side, and hole (1003b) is formed by irradiating the laser on double-sided copper-clad laminate 1000 from the second-surface (F2) side. Holes (1003a, 1003b) are formed at substantially the same position on the X-Y plane and then are connected to make through hole (300a) which penetrates through double-sided copper-clad laminate 1000. Through hole (300a) is shaped like an hourglass, for example. The boundary of hole (1003a) and hole (1003b) corresponds to narrowed portion (300c) (FIG. 1). Laser irradiation on first surface (F1) and laser irradiation on second surface (F2) may be conducted at the same time or one at a time. Desmearing is preferred to be conducted on through hole (300a) after through hole (300a) has been formed. Unwanted conduction (short circuiting) is suppressed by desmearing. Also, to enhance the absorption efficiency of laser light, a black-oxide treatment may be conducted on surfaces of metal foils (1001, 1002) prior to laser irradiation. Here, through hole (300a) may be formed by a drill or through etching instead of using a laser. However, it is easier to perform fine processing using a laser.

Using, panel plating, for example, copper plating 1004, for example, is formed on metal foils (1001, 1002) and in through hole (300a) as shown in FIG. 13C. Specifically, plating 1004 is formed by performing electroless plating first, and then by performing electrolytic plating in a plating solution using the electroless plated film as a seed layer. Accordingly, plating 1004 is filled in through hole (300a), and through-hole conductor (300b) is formed.

Each conductive layer formed on first surface (F1) or second surface (F2) of substrate 100 is patterned using an etching solution and an etching resist patterned by a lithographic technique, for example. Specifically, each conductive layer is covered by etching resist with a pattern corresponding to conductive layer 301 or 302, and portions of each conductive layer not covered by the etching resist (portions exposed through opening portions of the etching resist) are etched away. Such etching is not limited to a wet type, and a dry type may also be employed.

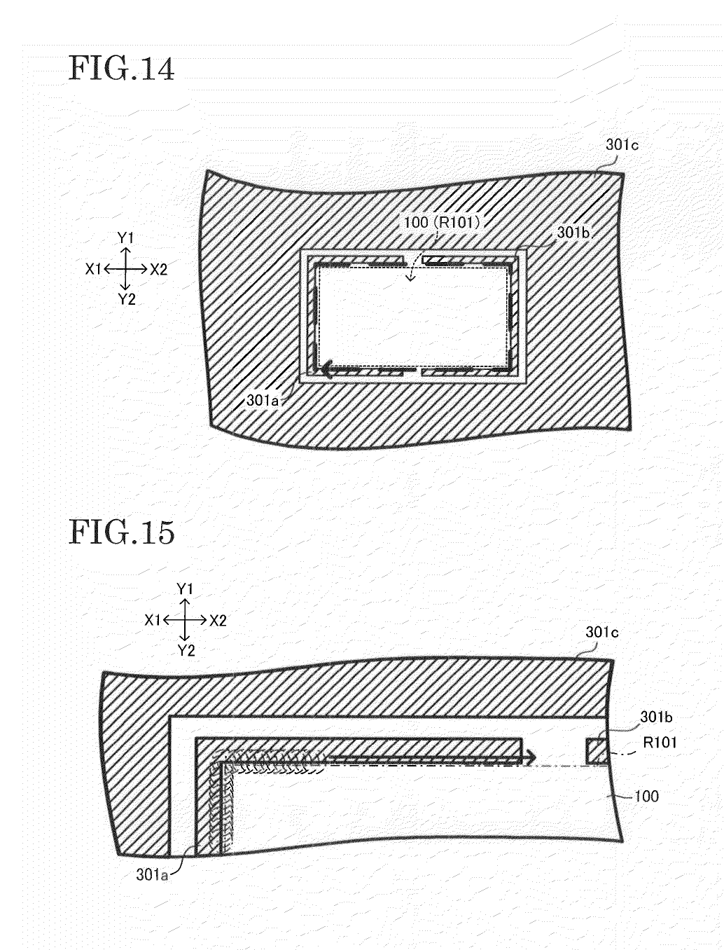

Accordingly, conductive layer 301 is formed on first surface (F1) of substrate 100, and conductive layer 302 is formed on second surface (F2) of substrate 100, as shown in FIG. 13D. Conductive patterns (301a, 301b, 301c) are included in conductive layer 301, and conductive patterns (302a, 302b, 302c) are included in conductive layer 302. On first surface (F1) of substrate 100, linear (U-shaped in particular) conductive patterns (301a, 301b) are formed to surround a predetermined region of first surface (F1), and on second surface (F2) of substrate 100, linear (U-shaped in particular) conductive patterns (302a, 302b) are formed to surround a predetermined region of second surface (F2). Conductive patterns (301a, 301b) are arrayed in direction X to face each other, and conductive patterns (302a, 302b) are arrayed in direction X to face each other (see FIG. 14).

In the present embodiment, before cavity (R10) (opening section (R100)) is formed, conductive patterns (301a, 301b, 301c) are formed along with other conductive patterns of conductive layer 301, and conductive patterns (302a, 302b, 302c) are formed along with other conductive patterns of conductive layer 302. At this stage, conductive pattern (301a) and conductive pattern (301b) are insulated from each other, and conductive pattern (302a) and conductive pattern (302b) are insulated from each other. Therefore, another separate step for insulating them is not required. In addition, when conductive layers (301, 302) are patterned as above, the sum of the lengths of conductive patterns (301a, 301b) is set at 85% or greater of the entire circumference of the first opening of cavity (R10) (opening section (R100)), and the sum of the lengths of conductive patterns (302a, 302b) is set at 85% or greater of the entire circumference of the second opening of cavity (R10) (opening section (R100)). Such conductive patterns (301a, 301b, 302a, 302b) are easy to obtain by using etching resist or plating resist patterned by a lithographic technique, for example.

In the present embodiment, conductive layers (301, 302) each have a triple-layer structure of copper foil (lower layer), electroless copper plating (middle layer) and electrolytic copper plating (upper layer), for example. In the present embodiment, conductive layers (301, 302) include power-source wiring. It is an option for conductive layer 301 or 302 to include a conductive pattern other than conductive patterns (301a, 301b, 301c) or (302a, 302b, 302c). Alignment marks to be used in a later step (such as a step for positioning electronic component 200) may be formed in conductive layer 301 or 302, for example.

Then, upper surfaces of conductive layers (301, 302) are each roughened by chemical etching, for example, if required. However, that is not the only option, and any other method may be used for roughening. The etching may be wet or dry etching.

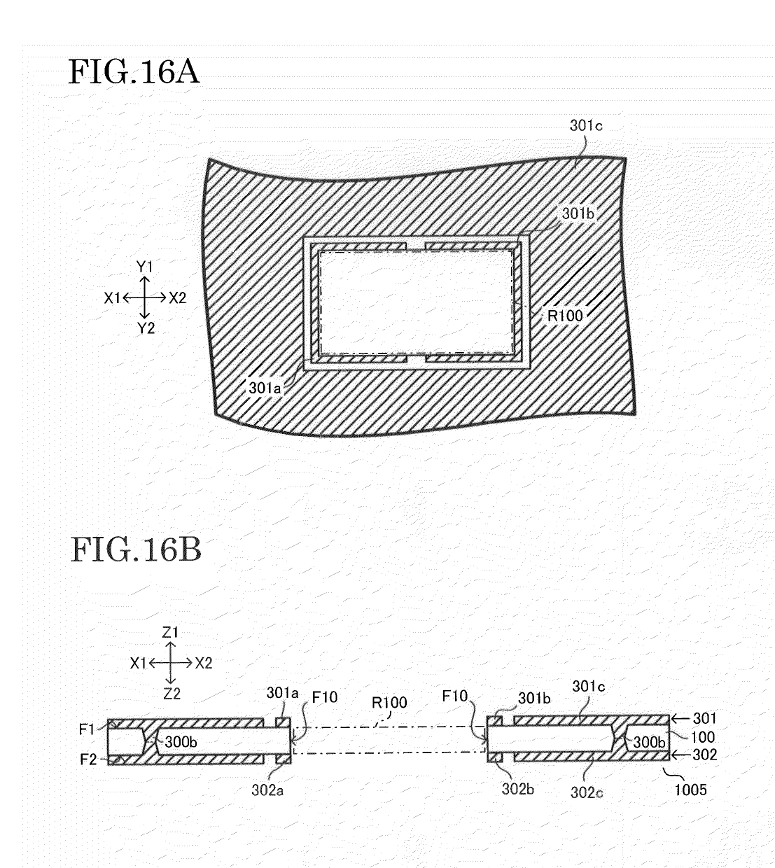

In step (S13) of FIG. 12, laser light is irradiated on substrate 100 from the first-surface (F1) side, for example, to form opening section (R100) in substrate 100 which opens on first surface (F1) and second surface (F2) respectively (see later-described FIGS. 16A, 16B). Specifically, as shown in FIG. 14 and FIG. 15 (partially enlarged view of FIG. 14), for example, while irradiating a laser at conductive patterns (301a, 301b) surrounding predetermined region (R101) (X-Y plane) of substrate 100, region (R101) surrounded by conductive patterns (301a, 301b) is cut out by a laser. Laser light is irradiated in a way to draw the shape of opening section (R100) (see FIG. 16A) along conductive patterns (301a, 301b). Using a laser, region (R101) corresponding to opening section (R100) of substrate 100 is cut out from the surrounding portions. The angle to irradiate the laser is set to be substantially perpendicular to first surface (F1) of substrate 100, for example.

In the present embodiment, while conductive patterns (301a, 301b) are irradiated by a laser, their inside region (R101) of substrate 100 is also irradiated by the laser. Since substrate 100 is protected by conductive patterns (301a, 301b), substrate 100 can be irradiated by a high intensity laser. By using a high intensity laser, cut surfaces are less likely to taper. As a result, processing accuracy is enhanced when forming a cavity, making it easier to form opening section (R100) (cavity) to have measurements as originally designed.

Also, since region (R101) is surrounded by conductive patterns (301a, 301b), the position and shape of region (R101) (opening section (R100)) are clear. Thus, it is easy to align laser irradiation.

During the laser irradiation above, a shading mask, for example, is not used. Laser irradiation is halted at portions where irradiation is not required so that laser light is irradiated only on portions that require irradiation. However, that is not the only option, and the entire surface of the target may be irradiated by laser light using a shading mask.

To move irradiation positions, a galvanometer mirror, for example, may be used to change irradiation positions of laser light, or a conveyor may be used to transport the irradiation target. Alternatively, a cylindrical lens, for example, may be used to make linear light from the light emitted from a laser.

Adjustment of laser intensity (amount of light) is preferred to be conducted by pulse control. Specifically, to change laser intensity, the laser intensity per shot (to irradiate once) is not changed, but the number of shots (irradiation number) is changed, for example. Namely, when required laser intensity is not obtained by one shot, laser light is irradiated again on the same irradiation spot. Using such a control method, throughput is thought to be improved since time for changing irradiation conditions is omitted. However, that is not the only option, and the method for adjusting laser intensity is determined freely. For example, irradiation conditions are set for each irradiation spot, and the number of irradiations may be set constant (for example, one shot per one irradiation spot).

For the formation of opening section (R100) (cavity), laser light may be irradiated only from one side of substrate 100, or laser light may be simultaneously irradiated from both sides of substrate 100. While irradiating a laser on conductive patterns (302a, 302b), the laser may also be irradiated on their inner portion of substrate 100. Moreover, after a hole with a bottom (non-penetrating hole) is formed by irradiating laser light from one side of substrate 100, laser light may be irradiated from the other side to penetrate through the bottom so that opening section (R100) (cavity) is formed.

If necessary, a black-oxide treatment is preferred to be conducted prior to laser irradiation. Also, after opening section (R100) is formed, desmearing or soft etching is preferred to be conducted if necessary.

Accordingly, as shown in FIG. 16A and FIG. 16B (a cross-sectional view of FIG. 16A), substrate 100 is obtained to have first surface (F1), its opposing second surface (F2) and opening section (R100) which penetrates from first surface (F1) to second surface (F2). In the present embodiment, opening section (R100) is made of a hole penetrating through substrate 100. Wall surfaces (F10) of substrate 100 facing opening section (R100) are substantially perpendicular to main surfaces of substrate 100, for example.

Opening section (R100) is formed as an accommodation space for electronic component 200. In the following, the section with a thickness from the upper surface of conductive layer 301 to the upper surface of conductive layer 302 (accommodation space for electronic component 200) is referred to as cavity (R10).

In step (S14) of FIG. 12, electronic component 200 is accommodated in cavity (R10) of substrate 100.

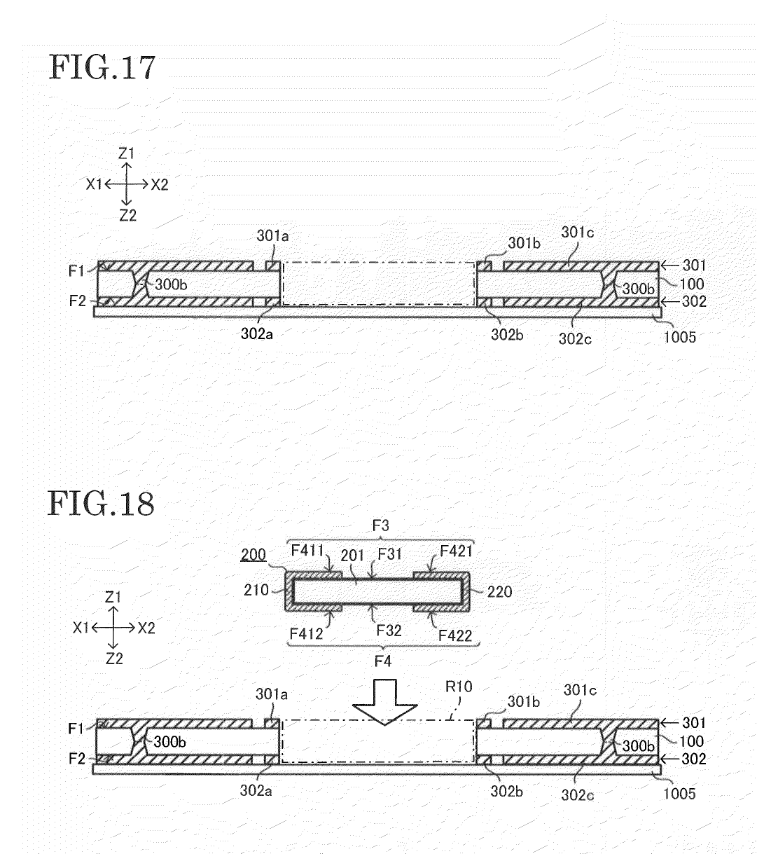

Specifically, as shown in FIG. 17, carrier 1005 made of PET (polyethylene terephthalate), for example, is provided on one side of substrate 100 (second surface (F2), for example). In doing so, one opening of cavity (R10) (hole) is covered by carrier 1005. In the present embodiment, carrier 1005 is an adhesive sheet (tape, for example), and is adhesive on the substrate 100 side. Carrier 1005 is adhered to substrate 100 (in particular, conductive layer 302) through lamination, for example.

As shown in FIG. 18, electronic component 200 is put into cavity (R10) from the side (the Z1 side) opposite the covered opening of cavity (R10) (hole).

First, electronic component 200 is prepared. Electronic component 200 has body 201 having first main surface (F31) and its opposing second main surface (F32), and electrodes (210, 220) (each an external electrode) formed on body 201. On first main surface (F31) and second main surface (F32) of body 201, portions of an external electrode (electrode 210 or 220) (upper portion (210a) and lower portion (210c), or upper portion (220a) and lower portion (220c)) are formed.

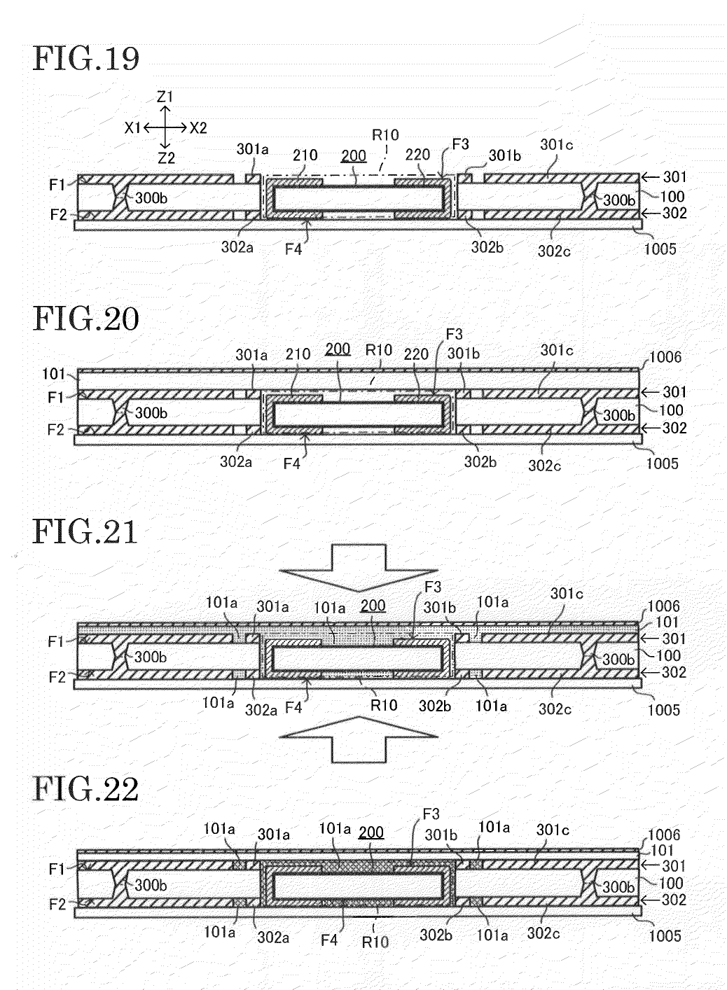

Electronic component 200 prepared above is put into cavity (R10) using a component mounter, for example. For example, electronic component 200 is held by a vacuum chuck or the like, transported to a portion above cavity (R10) (the Z1 side), lowered in a perpendicular direction, and put into cavity (R10). Accordingly, electronic component 200 is positioned in cavity (R10) (opening section (R100)) with third surface (F3) facing the same direction as first surface (F1) as shown in FIG. 19. Conductive pattern (301a) (first conductive pattern) is positioned near electrode 210 (first side electrode), and conductive pattern (301b) (second conductive pattern) is positioned near electrode 220 (second side electrode).

In step (S15) of FIG. 12, semicured (B-stage) insulation layer 101 and metal foil 1006 (such as copper foil with resin) are formed on conductive layer 301 as shown in FIG. 20. Insulation layer 101 is made of prepreg of thermosetting glass epoxy, for example. Resin is flowed out from insulation layer 101 into cavity (R10) by pressing semicured insulation layer 101 as shown in FIG. 21. Accordingly, insulator (101a) (resin from insulation layer 101) is filled between substrate 100 and electronic component 200 in cavity (R10) as shown in FIG. 22.

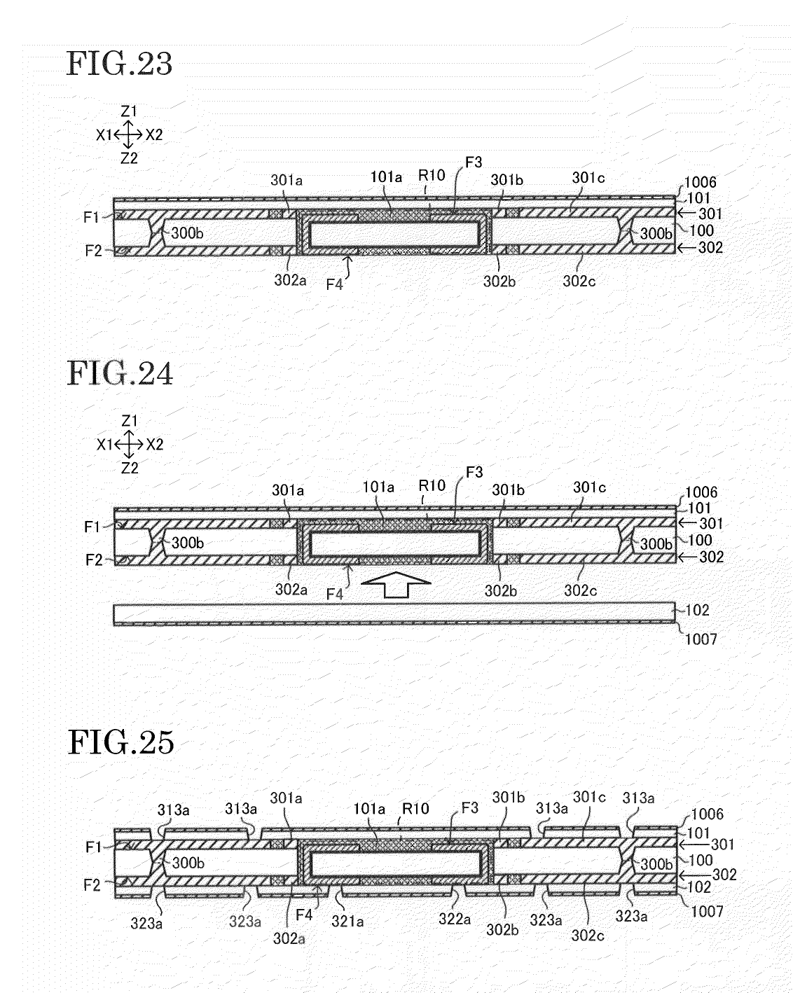

When insulator (101a) is filled in cavity (R10), the filler resin (insulator (101a)) and electronic component 200 are preliminarily adhered. In particular, filler resin is heated to a degree that it can support electronic component 200. By doing so, electronic component 200 supported by carrier 1005 is now supported by the filler resin. Then, carrier 1005 is removed as shown in FIG. 23.

At this stage, insulator (101a) (filler resin) and insulation layer 101 are only semicured, not completely cured. However, that is not the only option, and insulator (101a) and insulation layer 101 may be completely cured at this stage, for example.

Then, in step (S16) of FIG. 12, lower buildup sections are formed.

Specifically, as shown in FIG. 24, insulation layer 102 and metal foil 1007 (such as copper foil with resin) are formed on conductive layer 302 and on electrodes (210, 220) of electronic component 200. Insulation layer 102 is made of prepreg of thermosetting glass epoxy, for example. Semicured (B-stage) insulation layer 102 is adhered to conductive layer 302 and electrodes (210, 220) by pressing, for example, and is heated so that insulation layers (101, 102) are each cured.

Accordingly, a first insulation layer (insulation layer 101 and insulator (101a)) is formed on first surface (F1) of substrate 100, on conductive layer 301 and on third surface (F3) of electronic component 200; and a second insulation layer (insulation layer 102 and insulator (101a)) is formed on second surface (F2) of substrate 100, on conductive layer 302 and on fourth surface (F4) of electronic component 200 (see FIG. 25).

In the present embodiment, insulation layers (101, 102) are simultaneously cured. By simultaneously curing insulation layers (101, 102) formed on both surfaces of substrate 100, warping in substrate 100 is suppressed. As a result, it is easier to make substrate 100 thinner.

Here, resin may be flowed out from insulation layer 102 by the above pressing, and the resin that has flowed out from insulation layer 102 may also form insulator (101a) along with the resin that has flowed out from insulation layer 101.

Also, the above pressing and thermal treatment may be divided into multiple procedures. In addition, the thermal treatment and pressing may be conducted separately or simultaneously.

In the present embodiment, electronic component 200 is entirely accommodated in cavity (R10). Therefore, impact is less likely to be exerted on electronic component 200 in cavity (R10) during the above pressing.

As shown in FIG. 25, using a laser, for example, hole (313a) (via hole) is formed in insulation layer 101 and metal foil 1006, and holes (321a˜323a) (each a via hole) are formed in insulation layer 102 and metal foil 1007. Hole (313a) penetrates through metal foil 1006 and insulation layer 101, and holes (321a˜323a) each penetrate through metal foil 1007 and insulation layer 102. Then, hole (321a) reaches electrode 210 of electronic component 200, and hole (322a) reaches electrode 220 of electronic component 200. In addition, holes (313a, 323a) respectively reach conductive layers (301, 302) directly on through-hole conductor (300b). Then, desmearing is conducted if required.

In the present embodiment, since upper surfaces of electrodes (210, 220) are not roughened, high reflectance is maintained on the upper surfaces of electrodes (210, 220). Thus, damage to electrodes (210, 220) by laser is thought to be suppressed while forming via holes above.

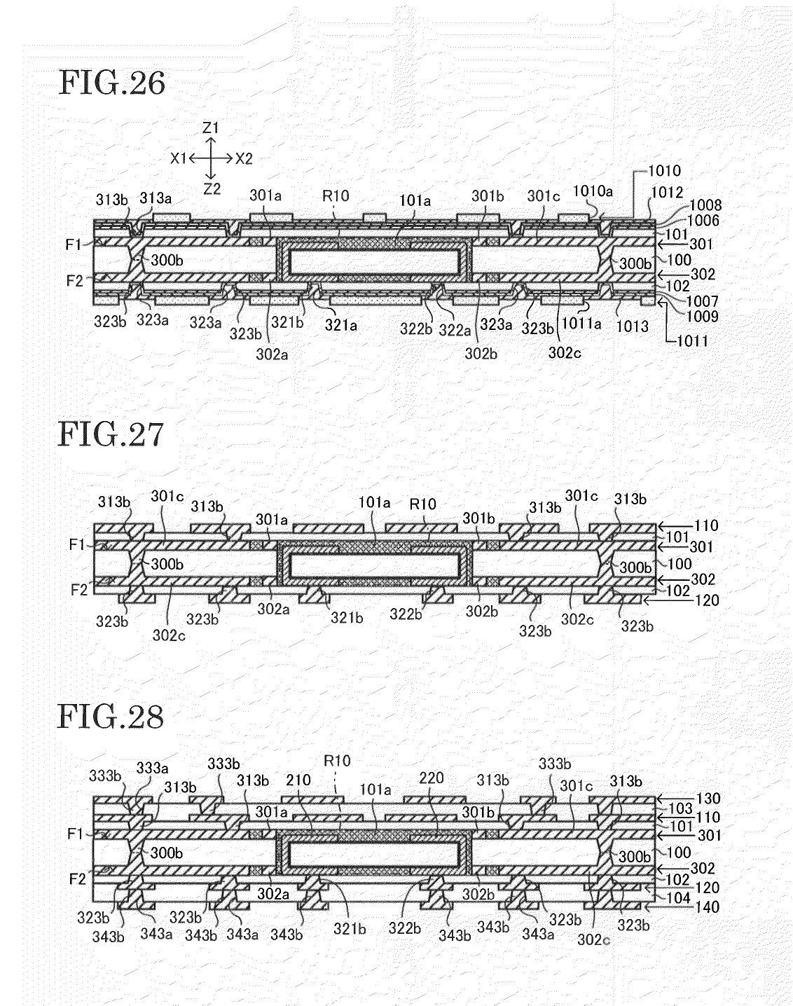

Using a chemical plating method, for example, electroless copper-plated films (1008, 1009), for example, are formed on metal foils (1006, 1007) and in holes (313a, 321a˜323a) (see FIG. 26). Here, prior to electroless plating, a catalyst made of palladium or the like may be adsorbed on surfaces of insulation layers (101, 102) through immersion, for example.

Using a lithographic technique, printing or the like, plating resist 1010 with opening portions (1010a) is formed on the first-surface (F1) side main surface (on electroless plated film 1008), and plating resist 1011 with opening portions (1011a) is formed on the second-surface (F2) side main surface (on electroless plated film 1009), (see FIG. 26). Opening portions (1010a, 1011a) are patterned corresponding to conductive layers (110, 120) respectively (FIG. 27).

As shown in FIG. 26, using a pattern plating method, for example, electrolytic copper platings (1012, 1013), for example, are respectively formed in opening portions (1010a, 1011a) of plating resists (1010, 1011). Specifically, copper as a plating material is connected to an anode, and electroless plated films (1008, 1009) as materials to be plated are connected to a cathode and immersed in a plating solution. Then, DC voltage is applied to flow current between both poles so that copper is deposited on surfaces of electroless plated films (1008, 1009). Accordingly, holes (313a, 321a˜323a) are filled with electroless plated films (1008, 1009) and electrolytic platings (1012, 1013), and via conductors (313b, 321b˜323b) made of copper plating, for example, are formed. Via conductor (321b) (first via conductor) is formed in insulation layer 102 (second insulation layer) and is connected to electrode 210 (first side electrode). Also, via conductor (322b) (second via conductor) is formed in insulation layer 102 (second insulation layer) and is connected to electrode 220 (second side electrode).

Then, using a predetermined removing solution, for example, plating resists (1010, 1011) are removed, and then unnecessary electroless plated films (1008, 1009) and metal foils (1006, 1007) are removed. Accordingly, conductive layers (110, 120) are formed as shown in FIG. 27. Upper surfaces of conductive layers (110, 120) are each roughened by chemical etching, for example. In the present embodiment, conductive layers (110, 120) each have a triple-layer structure of copper foil (lower layer), electroless copper plating (middle layer) and electrolytic copper plating (upper layer), for example. Accordingly, lower buildup sections are completed.

The seed layer for electrolytic plating is not limited to an electroless plated film. A sputtered film or the like may also be used as a seed layer instead of electroless plated films (1008, 1009).

In step (S17) of FIG. 12, upper buildup sections are formed as shown in FIG. 28, for example. The upper buildup sections are formed the same as the lower buildup sections, namely, by laminating and pressing insulation layers and metal foils (such as copper foil with resin), curing resin, forming via conductors and forming conductive layers (including a roughening treatment).

In step (S18) of FIG. 12, solder resist 11 with opening portions (11a) and solder resist 12 with opening portions (12a) are respectively formed on insulation layers (103, 104) and conductive layers (130, 140) (see FIG. 1). Conductive layers (130, 140) are respectively covered by solder resists (11, 12) except for predetermined spots corresponding to opening portions (11a, 12a) (pads (P11, P12) or the like). Solder resists (11, 12) are formed, for example, by screen printing, spray coating, roll coating, lamination or the like.

Using electrolytic plating, sputtering or the like, anticorrosion layers made of Ni/Au film, for example, are formed on conductive layers (130, 140), in particular, on surfaces of pads (P11, P12) not covered by solder resists (11, 12) (see FIG. 1). Anticorrosion layers made of organic protective film may also be formed by conducting an OSP treatment.

Wiring board 10 of the present embodiment (FIG. 1) is completed through the procedures described above. Then, if required, electrical tests (to check capacitance, insulation and the like) are conducted on electronic component 200.

The manufacturing method according to the present embodiment is suitable for manufacturing wiring board 10. Using such a manufacturing method, an excellent wiring board 10 is thought to be obtained at low cost.

Wiring board 10 of the present embodiment may be electrically connected to an electronic component or to another wiring board, for example. An electronic component (such as an IC chip) may be mounted on pads (P11) or (P12) of wiring board 10 through soldering, for example. Also, wiring board 10 may be mounted on another wiring board (such as a motherboard) through pads (P11) or (P12). Wiring board 10 of the present embodiment may be used as a circuit board of a mobile device such as a cell phone.

The present invention is not limited to the above embodiment. For example, the embodiment according to the present invention may also be modified as follows.

In the above embodiment, conductive patterns (301a, 301b, 302a, 302b) do not form circuits, and are electrically independent. However, that is not the only option. For example, conductive patterns (301a, 302a) may be set to have the same electrical potential as electrode 210 of electronic component 200 (electrical potential with the same polarity and the same absolute value); and conductive patterns (301b, 302b) may be set to have the same electrical potential as electrode 220 of electronic component 200 (electrical potential with the same polarity and the same absolute value). By setting such a structure, even if electrode 210 or 220 of electronic component 200 is electrically connected to conductive patterns (301a, 301b, 302a, 302b) for any reason, electronic component 200 seldom experiences operational abnormalities (or abnormal electrical characteristics).

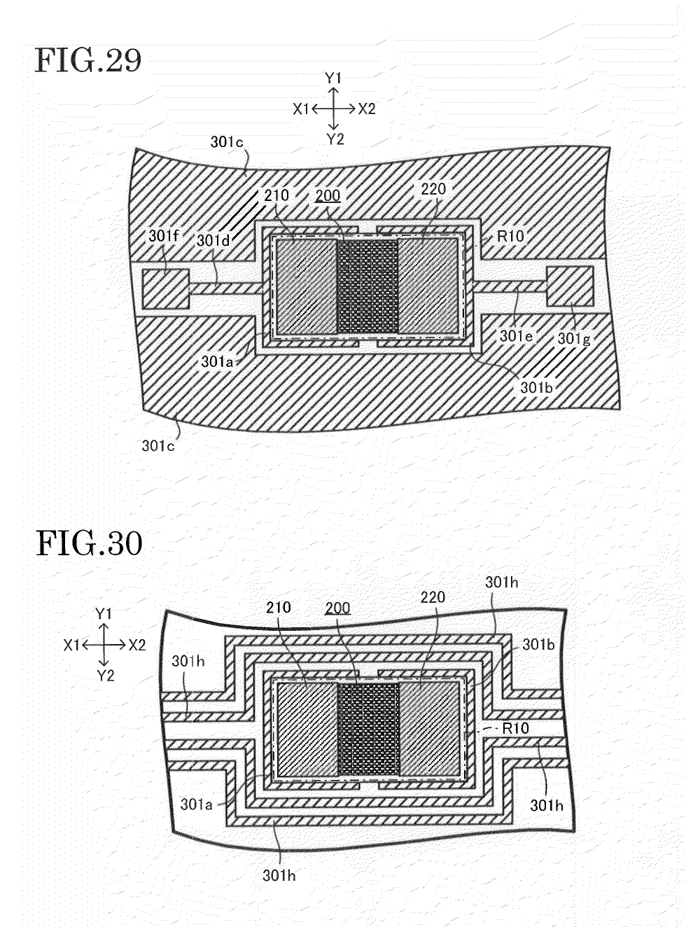

For conductive patterns (301a, 301b) to have the same electrical potential as electrodes (210, 220) of electronic component 200 respectively, it is effective for linear (U-shaped, in particular) conductive patterns (301a, 301b) to be connected respectively to planar conductive patterns (301f, 301g) (lands, for example) through linear conductive patterns (301d, 301e) or the like (wiring, for example) as shown in FIG. 29, for example. Here, conducive patterns (301a, 301b, 301c, 301d, 301e, 301f, 301g) are all included in conductive layer 301. In such a structure, by forming via conductors respectively connected to conductive patterns (301f, 301g), conductive patterns (301f, 301g) are electrically connected respectively to electrodes (210, 220) through upper-layer conductive patterns. The same applies when conductive patterns (302a, 302b) are respectively set to have the same electrical potential as electrodes (210, 220) of electronic component 200.

In the above embodiment, conductive layer 301 includes planar conductive pattern (301c) in addition to conductive patterns (301a, 301b), and conductive layer 302 includes planar conductive pattern (302c) in addition to conductive patterns (302a, 302b). However, that is not the only option, and as shown in FIG. 30, for example, conductive layer 301 may also include linear conductive patterns (301h) (wiring, for example) in addition to conductive patterns (301a, 301b). In such a case, the distance to cavity (R10) from a conductive pattern (301h) which is the closest to cavity (R10) among conductive patterns (301h) is preferred to be 70 μm or less. The same also applies to conductive layer 302.

The number of linear conductive patterns positioned near electrode 210 (first side electrode) and the number of linear conductive patterns positioned near electrode 220 (second side electrode) may be determined freely.

For example, as shown in FIG. 31A, conductive patterns (301a, 301b) may each be formed with one U-shaped conductive pattern and two I-shaped conductive patterns (straight patterns). As shown in FIG. 31B, for example, conductive patterns (301a, 301b) may each be formed with three I-shaped conductive patterns (straight patterns). As shown in FIG. 31C, for example, conductive patterns (301a, 301b) may each be formed with two L-shaped conductive patterns. In those situations as well, among multiple linear conductive patterns surrounding the first opening, the entire conductive pattern (301a) positioned near electrode 210 is preferred to be positioned in first peripheral portion (R11) of the cavity (FIG. 6A) with which electrode 220 never makes contact; among multiple linear conductive patterns surrounding the first opening, the entire conductive pattern (301b) positioned near electrode 220 is preferred to be positioned in second peripheral portion (R21) of cavity (R10) (FIG. 6B) with which electrode 210 never makes contact. In addition, the sum of the lengths of multiple linear conductive patterns surrounding the first opening is preferred to be 85% or greater of the entire circumference of the first opening of cavity (R10). Here, the same also applies to conductive layer 302.

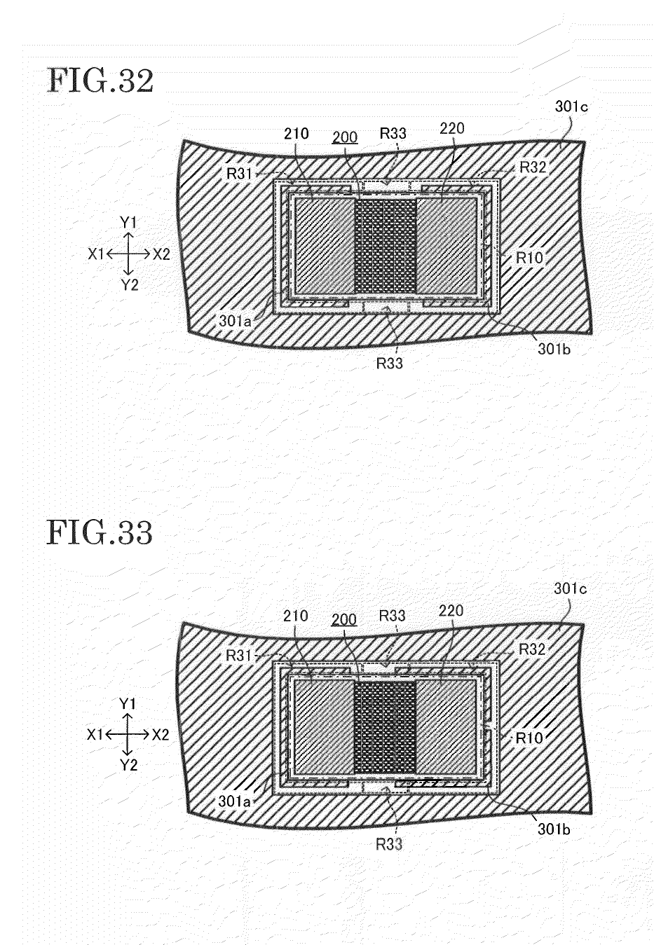

As shown in FIG. 32, entire conductive pattern (301a) may be formed on fifth peripheral portion (R31), and entire conductive pattern (301b) may be formed on sixth peripheral portion (R32). Also, as shown in FIG. 33, conductive pattern (301a) and conductive pattern (301b) may have asymmetric shapes relative to cavity (R10). Here, the same also applies to conductive layer 302.

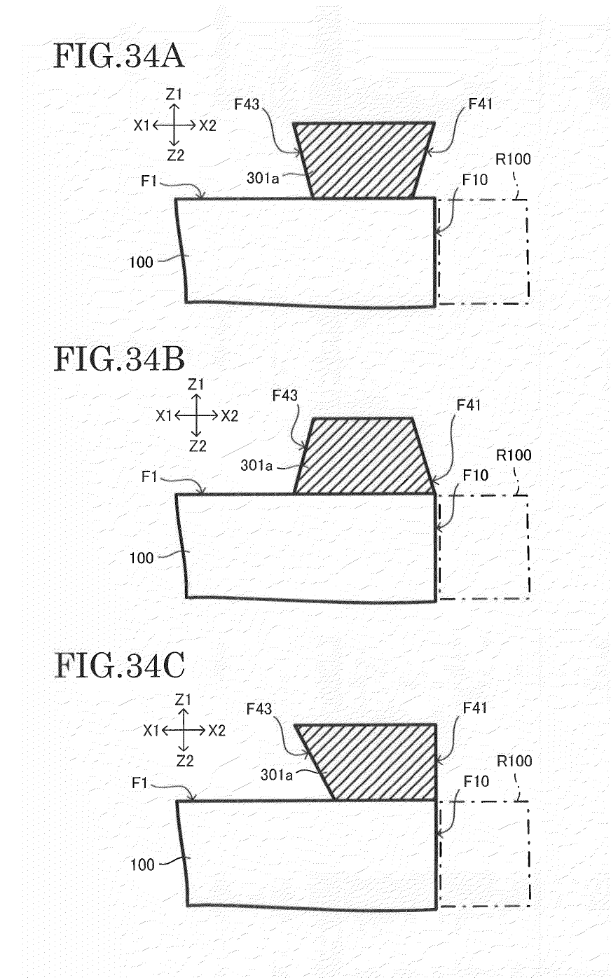

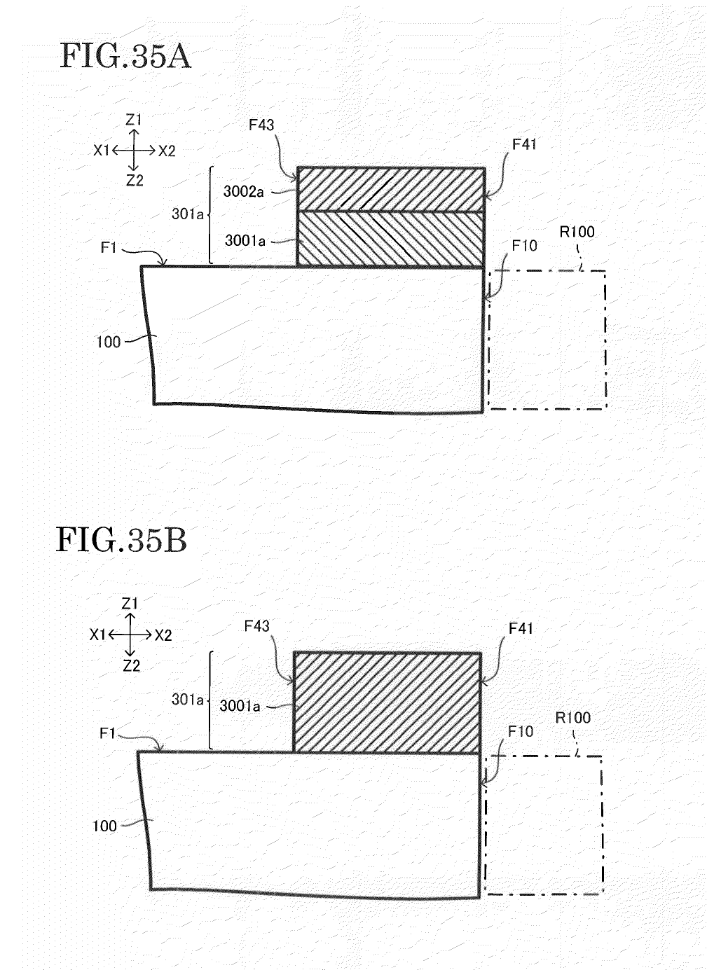

As shown in FIG. 34A or 34B, the angle of each side surface of conductive pattern (301a) (side surfaces (F41, F43)) to first surface (F1) of substrate 100 may be acute or obtuse. Also, as shown in FIG. 34C, side surface (F41) may intersect with first surface (F1) of substrate 100 at substantially right angles, while the angle of side surface (F43) to first surface (F1) of substrate 100 is acute. In addition, the layer structure of conductive pattern (301a) may be determined freely. For example, as shown in FIG. 35A, conductive pattern (301a) may be double layered with first layer (3001a) made of electroless copper plating, for example, and second layer (3002a) made of electrolytic copper plating, for example. Also, as shown in FIG. 35B, for example, conductive pattern (301a) may be single layered with first layer (3001a) made of copper foil, for example. Here, the same also applies to conductive pattern (301b) or conductive layer 302.

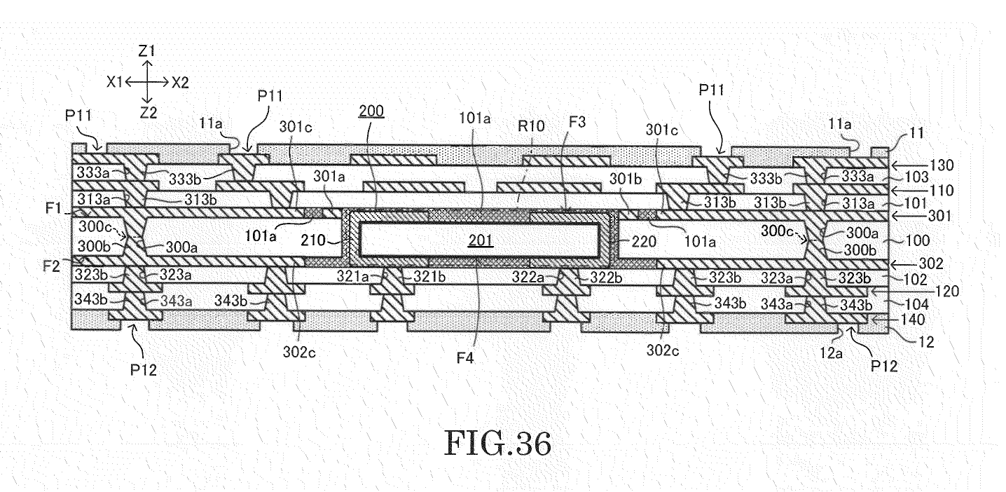

Wiring board 10 of the above embodiment has linear conductive patterns (301a, 301b) surrounding the first opening of cavity (R10) as well as linear conductive patterns (302a, 302b) surrounding the second opening of cavity (R10). However, that is not the only option, and even if conductive patterns (302a, 302b) are omitted as shown in FIG. 36, for example, the processing accuracy of forming a cavity is also enhanced.

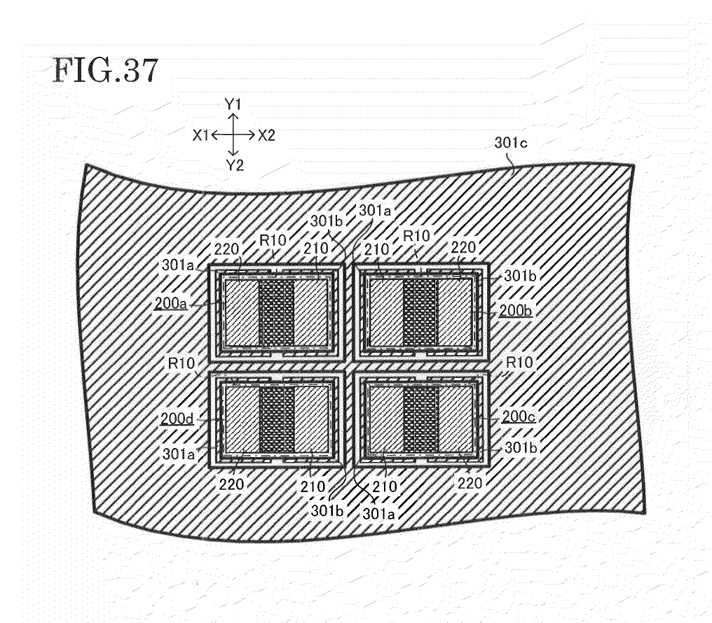

As shown in FIG. 37, by forming multiple cavities (R10) in substrate 100, and by accommodating an electronic component in each cavity (R10), a wiring board with multiple built-in electronic components (electronic components (200a, 200b, 200c, 200d)), for example) is obtained.

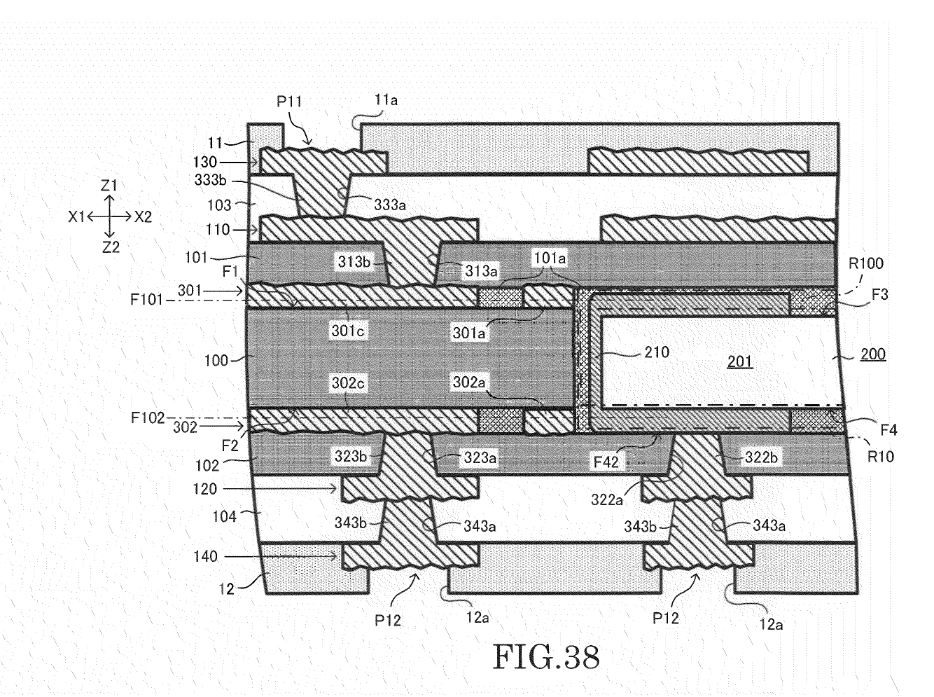

In the above embodiment, insulation layers (101, 102, 103, 104) are each made of resin containing core material. However, that is not the only option. For example, it is especially important for insulation layers (101, 102) which form lower buildup sections to be made of resin containing core material so as to maintain the flatness of each interlayer insulation layer. Thus, as shown in FIG. 38, for example, even if insulation layers (103, 104) do not contain core material, as long as insulation layers (101, 102) contain core material, the required flatness is most likely to be obtained. Here, whether or not an interlayer insulation layer contains core material is shown by hatching in FIG. 38. Also, if required flatness is secured, none of insulation layers (101, 102, 103, 104) needs to contain core material.

In the above embodiment, electronic component 200 has a single-sided via structure. However, that is not the only option. For example, as shown in FIG. 39, it is also an option for a wiring board to have via conductors (311b, 312b, 321b, 322b) electrically connected to electrodes (210, 220) of electronic component 200 on both sides of electronic component 200.

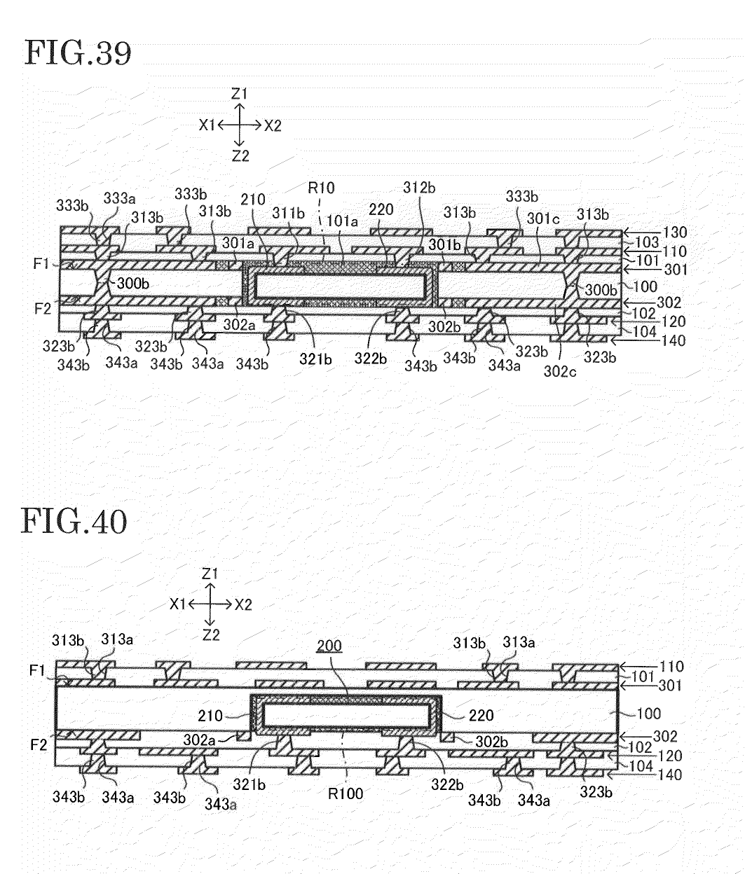

As shown in FIG. 40, non-penetrating opening section (R100) (cavity) which opens on second surface (F2) may be formed in substrate 100, and electronic component 200 may be positioned in such opening section (R100).

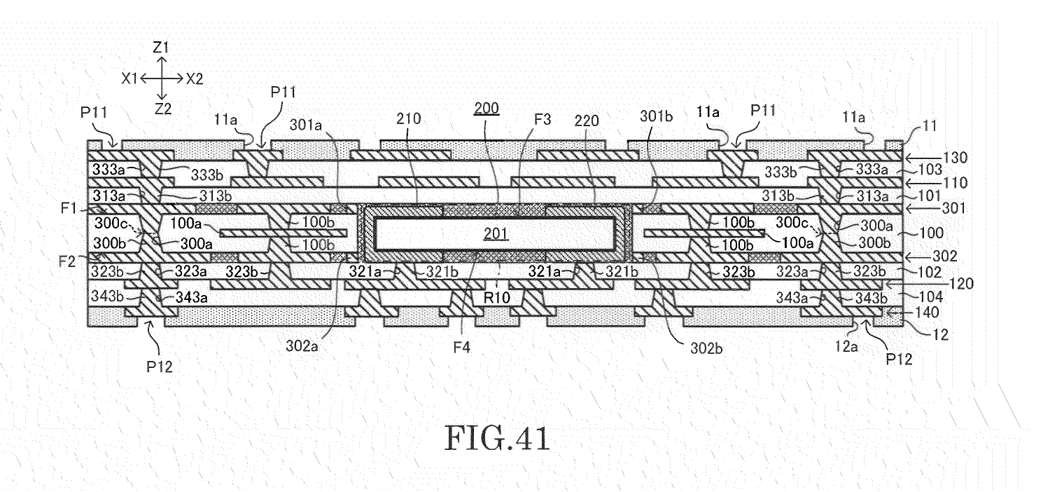

As shown in FIG. 41, substrate 100 (the core substrate of a wiring board, for example) may be an insulative substrate with a built-in metal plate (100a) (copper foil, for example). In such substrate 100, heat dissipation is improved because of metal plate (100a). In the example shown in FIG. 41, via conductors (100b) reaching metal plate (100a) are formed in substrate 100, and then metal plate (100a) and power-source wiring lines (conductive layers (301, 302) electrically connected to ground, for example) are electrically connected to each other by via conductors (100). The planar shape (X-Y plane) of metal plate (100a) is determined freely. It may be rectangular or circular.

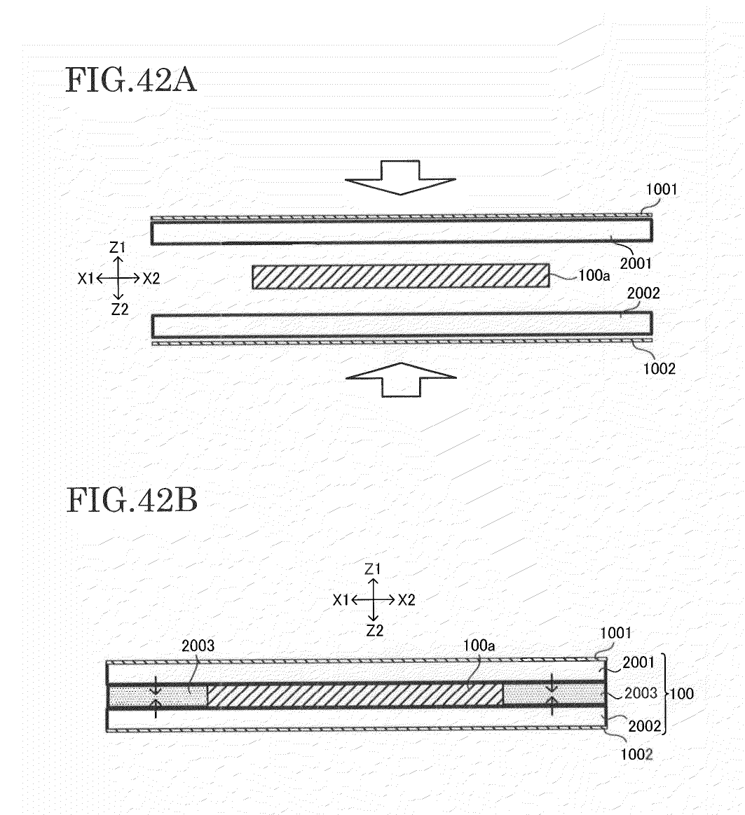

A method for manufacturing substrate 100 (core substrate) shown in FIG. 41 is described below by referring to FIGS. 42A and 42B.

First, as shown in FIG. 42A, insulation layer 2001 and metal foil 1001 (such as copper foil with resin) along with insulation layer 2002 and metal foil 1002 (such as copper foil with resin) are positioned to sandwich metal plate (100a) made of copper foil, for example. Insulation layers (2001, 2002) are each made of prepreg of glass epoxy, for example.

Pressure is exerted toward metal plate (100a) by pressing. By pressing semicured (B-stage) insulation layers (2001, 2002), resin is flowed out from insulation layers (2001, 2002) as shown in FIG. 42B. Accordingly, insulation layer 2003 is formed on sides of metal plate (100a). Then, insulation layers (2001, 2002, 2003) are each heated to be cured. Accordingly, substrate 100 with built-in metal plate (100a) is completed.

The above pressing and thermal treatments may be divided into multiple procedures. Also, the thermal and pressing treatments may be conducted separately or simultaneously.

The electrodes of a chip capacitor to be accommodated in cavity (R10) (opening section) may be in any shape.

An electronic component to be accommodated in cavity (R10) (opening section) may be of any kind. Any electronic component, for example, active components such as an IC chip in addition to passive components such as a capacitor, resistor or coil, may be used. Also, the electronic component to be accommodated in cavity (R10) may be such that multiple elements (such as capacitors) are integrated (molded, for example).

The structure of wiring board 10, especially, the type, quality, measurements, material, shape, number of layers, positions and the like of its structural elements may be modified freely within a scope that does not deviate from the gist of the present invention.

For example, the number of layers in a buildup section is determined freely. Also, the number of layers in buildup sections may be different on the first-surface (F1) side of substrate 100 and on the second-surface (F2) side of substrate 100. However, to mitigate stress, it is preferred to enhance symmetry on the upper and lower surfaces by setting the same number of layers in buildup sections on the first-surface (F1) side of substrate 100 and on the second-surface (F2) side of substrate 100.

Each via conductor is not limited to a filled conductor. It may be a conformal conductor, for example.

Opening section (R100) (cavity) and an electronic component accommodated in the opening section may be in any planar shape (X-Y plane); for example, they may be substantially a circle, or substantially a polygon such as substantially a square, substantially a hexagon, substantially an octagon or the like in addition to substantially a rectangle. Corners of such polygons may have any angle, for example, substantially right angles, acute or obtuse angles, or even be roundish. However, to reduce the size of opening section (R100) (cavity) for purposes of increasing wiring regions on the substrate, the planar shape (X-Y plane) of the opening section (accommodation section) is preferred to correspond to the planar shape (X-Y plane) of the electronic component to be accommodated.

The method for manufacturing a wiring board is not limited to the order and contents as shown in FIG. 12 above. The order and contents may be freely modified within a scope that does not deviate from the gist of the present invention. In addition, some step may be omitted according to usage or the like.

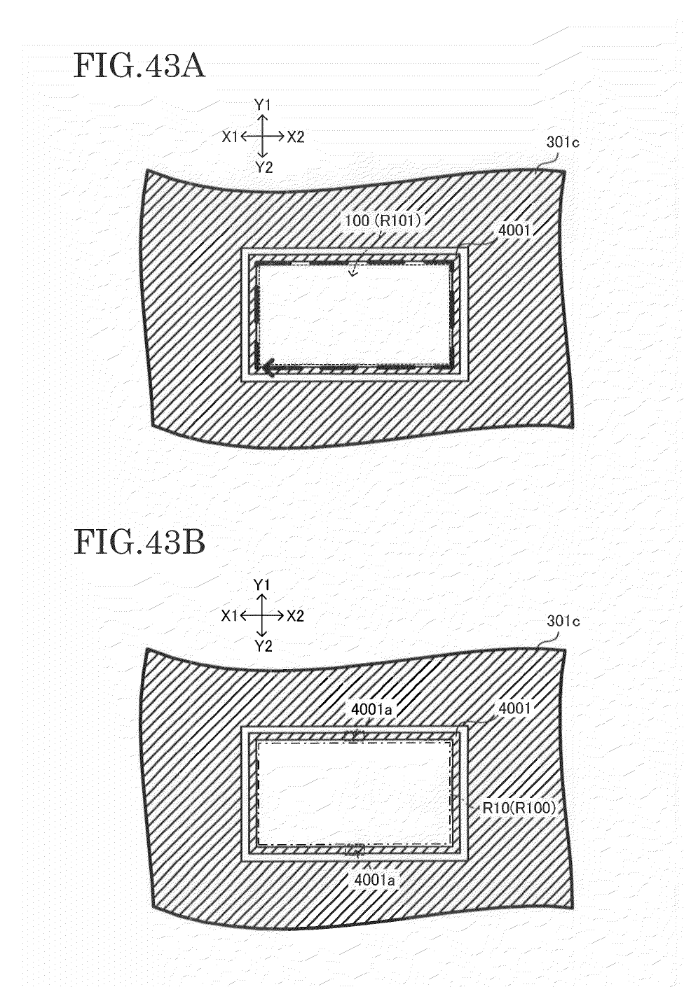

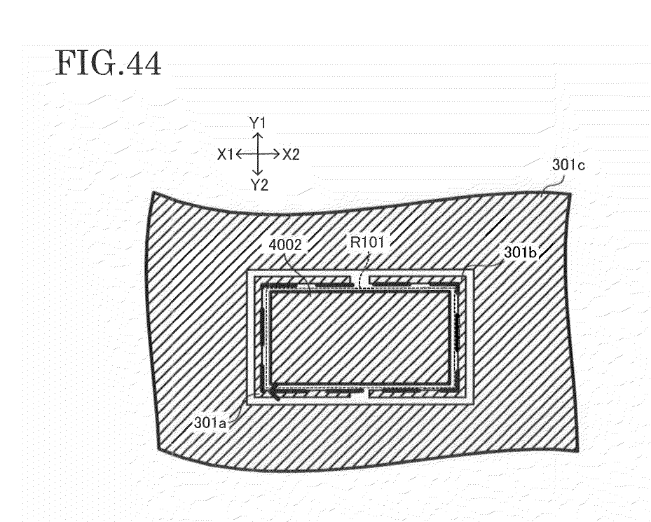

In the above embodiment, conductive pattern (301a) (conductive pattern positioned near electrode 210) and conductive pattern (301b) (conductive pattern positioned near electrode 220) which surround predetermined region (R101) are insulated from each other prior to forming cavity (R10). However, that is not the only option. For example, the following procedure may also be taken: first, ring-shaped conductive pattern 4001 without a break is formed on first surface (F1) of substrate 100 as shown in FIG. 43A (view corresponding to FIG. 14); then, along conductive pattern 4001 (in particular, while irradiating a laser on conductive pattern 4001), a laser is irradiated inside conductive pattern 4001 (region (R101) of substrate 100 surrounded by conductive pattern 4001) to form cavity (R10) as shown in FIG. 43B; and then, predetermined portions (4001a) (two portions shown in FIG. 43B, for example) of conductive pattern 4001 are removed by etching, laser or the like. By removing portions (4001a), conductive pattern (301a) (conductive pattern positioned near electrode 210) and conductive pattern (301b) (conductive pattern positioned near electrode 220) which surround the first opening of cavity (R10) (opening section (R100)) are insulated from each other. Once insulation layer 101 is formed, it is difficult to process conductive layer 301 on substrate 100 (core section). Thus, it is preferred to insulate conductive pattern (301a) and conductive pattern (301b) from each other before insulation layer 101 is formed. Here, the same also applies to conductive layer 302.

Also, as shown in FIG. 44 (view corresponding to FIG. 14), planar conductive pattern 4002 may be left in region (R101) of substrate 100 surrounded by conductive patterns (301a, 301b) when forming conductive layer 301. In doing so, conductive layer 301 on substrate 100 is removed along the laser irradiation path when cavity (R10) is formed. Here, the same also applies to conductive layer 302.

For example, the method for forming each conductive layer is not limited specifically. For example, any one or a combination of any two or more of the following may be used to form conductive layers: panel plating, pattern plating, full-additive, semi-additive (SAP), subtractive, transfer and tenting methods.

For example, when isotropic etching using etching resist (wet etching, for example) is employed to pattern conductive layer 301, it is easy to form the structure shown in FIG. 34A for conductive patterns (301a, 301b) using side etching.

For example, when conductive layer 301 is formed by a pattern plating method using plating resist, it is easy to form the structure shown in FIG. 34B for conductive patterns (301a, 301b).

In addition, wet or dry etching may be employed instead of using a laser. When etching is conducted, it is considered preferable to protect in advance by resist or the like a portion that is not required to be removed.

The above embodiment and modified examples may be combined freely. It is considered preferable to select an appropriate combination according to usage or the like. For example, any structure shown in FIGS. 29˜40 may be applied to a substrate with a built-in metal plate shown in FIG. 41. Also, the manufacturing method shown in FIGS. 43A and 43B may be combined with the manufacturing method shown in FIG. 44.

A wiring board with a built-in electronic component according to an embodiment of the present invention has the following: a substrate with a first surface and its opposing second surface, in which a cavity is formed to open at least on the first surface; an electronic component which is positioned in the cavity and has a first side electrode and its opposing second side electrode; an insulation layer formed on the first surface of the substrate and on the electronic component; and a conductive layer formed on the first surface of the substrate. In such a wiring board, the conductive layer includes multiple linear conductive patterns surrounding the first-surface side opening of the cavity, and among the multiple linear conductive patterns surrounding the opening, a conductive pattern positioned near the first side electrode and a conductive pattern positioned near the second side electrode are insulated from each other.

A method for manufacturing a wiring board with a built-in electronic component according to another embodiment of the present invention includes the following: preparing a substrate which has a first surface and its opposing second surface; on the first surface of the substrate, forming a conductive layer that includes multiple linear conductive patterns surrounding a predetermined region of the first surface; in the substrate, forming a cavity which opens at least on the first surface; preparing an electronic component which has a first side electrode and its opposing second side electrode; positioning the electronic component in the cavity; and forming an insulation layer on the first surface of the substrate and on the electronic component. In such a manufacturing method, when forming the cavity, a laser is irradiated on the multiple linear conductive patterns surrounding the predetermined region so that the region surrounded by the multiple linear conductive patterns is cut out by the laser to form the cavity in the substrate, and among the multiple linear conductive patterns surrounding the predetermined region, a conductive pattern positioned near the first side electrode and a conductive pattern positioned near the second side electrode are insulated from each other at least when forming the insulation layer.

According to an embodiment of the present invention, the clearance between a cavity and an electronic component positioned inside it is reduced. In addition, processing accuracy is enhanced when forming a cavity. A wiring region on the substrate is enlarged. The substrate tends not to warp. Positional shifting between an electrode of an electronic component and a via conductor connected to the electrode is suppressed. Short circuiting is suppressed between electrodes of the electronic component built into a wiring board.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board, comprising:
a substrate having a cavity;
an electronic component positioned in the cavity and having a first-side electrode on one side of the electronic component and a second-side electrode on an opposite side of the electronic component;
an insulation layer formed on a surface of the substrate and the electronic component such that the insulation layer covers the electronic component positioned in the substrate; and
a conductive layer formed on the surface of the substrate and comprising a plurality of linear conductive patterns surrounding an opening of the cavity on the surface of the substrate,
wherein the plurality of linear conductive patterns includes a first linear conductive pattern positioned adjacent to the first-side electrode and a second linear conductive pattern positioned adjacent to the second-side electrode such that the first linear conductive pattern and the second linear conductive pattern are insulated from each other.

2. The wiring board with a built-in electronic component according to claim 1, wherein the first linear conductive pattern and the second linear conductive pattern have shapes symmetrical to each other relative to the cavity.

3. The wiring board with a built-in electronic component according to claim 1, wherein the first linear conductive pattern has a planar U-shape facing three sides of the first-side electrode, and the second linear conductive pattern has a planar U-shape facing three sides of the second-side electrode.

4. The wiring board with a built-in electronic component according to claim 1, wherein the first linear conductive pattern is formed in a plurality and formed in a first peripheral portion of the cavity, and the second linear conductive pattern is formed in a plurality and formed in a second peripheral portion of the cavity.

5. The wiring board with a built-in electronic component according to claim 1, wherein the plurality of linear conductive patterns has edge surfaces substantially aligning with wall surfaces of the cavity.

6. The wiring board with a built-in electronic component according to claim 1, wherein the cavity has walls which are cut surfaces contiguous to edge surfaces of the linear conductive patterns.

7. The wiring board with a built-in electronic component according to claim 1, wherein each of the linear conductive patterns has one of an I-shape, an L-shape and a U-shape.

8. The wiring board with a built-in electronic component according to claim 1, wherein the cavity is formed by a laser.

9. The wiring board with a built-in electronic component according to claim 1, further comprising a second insulation layer formed on an opposite surface of the substrate with respect to the insulation layer, wherein the cavity of the substrate is penetrating from the surface to the opposite surface, and the second insulation layer covers the electronic component.

10. The wiring board with a built-in electronic component according to claim 1, wherein the plurality of linear conductive patterns has a same width with respect to each other.

11. The wiring board with a built-in electronic component according to claim 1, wherein each of the linear conductive patterns has a width in a range of 30 μm or less.

12. The wiring board with a built-in electronic component according to claim 1, wherein the plurality of linear conductive patterns has a same thickness with respect to each other.

13. The wiring board with a built-in electronic component according to claim 1, wherein the plurality of linear conductive patterns has a sum of lengths which is 85% or greater of an entire circumference of the opening of the cavity.

14. The wiring board with a built-in electronic component according to claim 1, wherein the conductive layer includes a metal foil formed on the substrate and a plated film formed on the metal foil.

15. The wiring board with a built-in electronic component according to claim 1, wherein the conductive layer forms a same thickness.

16. The wiring board with a built-in electronic component according to claim 1, wherein at least one of the substrate and the insulation layer includes a resin and a core material incorporated in the resin.

17. The wiring board with a built-in electronic component according to claim 1, wherein the electronic component has a body having a first main surface, a second main surface on an opposite side of the first main surface of the body, a first side surface between the first main surface and the second main surface, and a second side surface on an opposite side of the first side surface of the body between the first main surface and the second main surface, the first-side electrode is formed on the first main surface, the first side surface and the second main surface of the body, and the second-side electrode is formed on the first main surface, the second side surface and the second main surface of the body.

18. The wiring board with a built-in electronic component according to claim 1, wherein the electronic component is a laminated ceramic capacitor.

19. The wiring board with a built-in electronic component according to claim 1, wherein the cavity and the electronic component has a clearance which is set in a range of 60 μm or less in a direction in which the first-side electrode and the second-side electrode are arrayed.

20. The wiring board with a built-in electronic component according to claim 22, wherein the cavity and a conductive pattern closest to the cavity among the linear conductive patterns has a distance which is set at 70 μm or less between the cavity and the conductive pattern closest to the cavity.

21. The wiring board with a built-in electronic component according to claim 1, further comprising:
a first via conductor formed in the insulation layer and electrically connected to the first-side electrode; and
a second via conductor formed in the insulation layer and electrically connected to the second side electrode.

22. A method for manufacturing a wiring board with a built-in electronic component, comprising:
forming on a first surface of a substrate a conductive layer comprising a plurality of linear conductive patterns surrounding a predetermined region of the first surface;
forming in the predetermined region of the substrate a cavity having an opening at least on the first surface;
positioning in the cavity an electronic component having a first-side electrode and a second-side electrode on an opposite side of the first-side electrode; and
forming an insulation layer on the first surface of the substrate and the electronic component such that the insulation layer covers the electronic component,
wherein the forming of the cavity comprises irradiating laser on the plurality of linear conductive patterns such that the region surrounded by the plurality of linear conductive patterns is cut out and that the cavity is formed in the predetermined region of the substrate, and the positioning of the electronic component comprises placing the electronic component in the cavity such that the plurality of linear conductive patterns includes a first linear conductive pattern positioned adjacent to the first-side electrode and a second linear conductive pattern positioned adjacent to the second-side electrode and that the first linear conductive pattern and the second linear conductive pattern are insulated from each other at least through the forming of the insulation layer.
